(19) United States
(12) Patent Application Publication
(10) Pub. No.: US 2024/0224463 A1
(43) Pub. Date: Jul. 4, 2024

(54) METHODS AND APPARATUS FOR FAN CONTROL

(71) Applicant: Intel Corporation, Santa Clara, CA (US)

(72) Inventors: Ali Kalantarian, Richmond Hill (CA); Saanjali Maharaj, Toronto (CA); Tejas Shah, Austin, TX (US); Tamara Low Foon, Toronto (CA); Mirui Wang, Oshawa (CA)

(21) Appl. No.: 18/147,522

(22) Filed: Dec. 28, 2022

(51) Int. Cl. H05K 7/20; G06F 1/20

(52) U.S. Cl. CPC H05K 7/20209; G06F 1/206; H05K 7/20154; H05K 7/20172

(57) ABSTRACT

Methods, apparatus, systems, and articles of manufacture are disclosed. An example system includes interface circuitry; first programmable circuitry; and instructions to cause the first programmable circuitry to: determine, based on a first signal output by a first sensor, a first temperature at a first location that is associated with second programmable circuitry; determine, based on a second signal output by a second sensor, a second temperature at a second location that is different than the first location; set a first thermal setpoint for the second programmable circuitry in response to the second temperature failing to satisfy a threshold value; and set a second thermal setpoint for the second programmable circuitry in response to the second temperature satisfying the threshold value, wherein the second thermal setpoint is higher than the first thermal setpoint.

### BACKGROUND

Processing units such as graphical processing units (GPUs) infrastructure processing units (IPUs), neural network accelerators, network accelerators, etc., generate heat during operation. Processing units may include a heatsink to absorb the heat and facilitate dissipation of the heat to regulate the temperature of the hardware. Some processing units include fans to increase airflow at the heatsink and, thus, the dissipation of the heat.

### BRIEF DESCRIPTION OF THE DRAWINGS

FIG. 1 illustrates one or more example environments in which teachings of this disclosure may be implemented.

FIG. 2 illustrates at least one example of a data center for executing workloads with disaggregated resources.

FIG. 3 illustrates at least one example of a pod that may be included in the data center of FIG. 2.

FIG. 4 is a perspective view of at least one example of a rack that may be included in the pod of FIG. 3.

FIG. 5 is a side elevation view of the rack of FIG. 4.

FIG. 6 is a perspective view of the rack of FIG. 4 having a sled mounted therein.

FIG. 7 is a is a block diagram of at least one example of a top side of the sled of FIG. 6.

FIG. 8 is a block diagram of at least one example of a bottom side of the sled of FIG. 7.

FIG. 9 is a block diagram of at least one example of a compute sled usable in the data center of FIG. 2.

FIG. 10 is a top perspective view of at least one example of the compute sled of FIG. 9.

FIG. 11 is a block diagram of at least one example of an accelerator sled usable in the data center of FIG. 2.

FIG. 12 is a top perspective view of at least one example of the accelerator sled of FIG. 10.

FIG. 13 is a block diagram of at least one example of a storage sled usable in the data center of FIG. 2.

FIG. 14 is a top perspective view of at least one example of the storage sled of FIG. 13.

FIG. 15 is a block diagram of at least one example of a memory sled usable in the data center of FIG. 2.

FIG. 16 is a block diagram of a system that may be established within the data center of FIG. 2 to execute workloads with managed nodes of disaggregated resources.

FIG. 17 is an illustration of an example GPU and example control circuitry.

FIG. 18 is a block diagram of an example implementation of the control circuitry of FIG. 17.

FIG. 19 is a block diagram of a control loop that may be executed by the control circuitry of FIG. 17.

FIG. 20 is an illustration of example operations of the control circuitry of FIG. 18 for set target temperature fan control using ambient temperature.

FIG. 21 is a continuation of the illustration of FIG. 20.

FIG. 22 is a flowchart representative of machine readable instructions that may be executed by processor circuitry to implement the control circuitry 1704 of FIG. 17.

FIG. 23 is a flowchart representative of machine readable instructions that may be executed by processor circuitry to select a thermal setpoint.

FIG. 24 is an illustration of performance gains that may be achieved using techniques described herein.

FIG. 25 is a block diagram of an example processing platform including processor circuitry structured to execute the example machine readable instructions and/or the example operations of FIG. 17 to implement the control circuitry 1704 of FIG. 17.

FIG. 26 is a block diagram of an example implementation of the processor circuitry of FIG. 25.

FIG. 27 is a block diagram of another example implementation of the processor circuitry of FIG. 25.

FIG. 28 is a block diagram of an example software distribution platform (e.g., one or more servers) to distribute software (e.g., software corresponding to the example machine readable instructions of FIGS. 20-23) to client devices associated with end users and/or consumers (e.g., for license, sale, and/or use), retailers (e.g., for sale, re-sale, license, and/or sub-license), and/or original equipment manufacturers (OEMs) (e.g., for inclusion in products to be distributed to, for example, retailers and/or to other end users such as direct buy customers).

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time+/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Thermal engineers must delicately balance the tradeoff between thermal performance and fan noise when optimizing fan control methods for processing units (e.g., GPUs, CPUs, IPUs, etc.). Balancing these conflicting tradeoffs presents significant challenges. Prior fan control solutions struggle under ever-increasing performance demands of modern computing workloads, which require significant cooling airflow. The shortcomings of prior GPU thermal solutions are exacerbated by the continual miniaturization of compute components, which increases the need for small, rapidly rotating fans to drive cooling air over increasingly small areas. Fans that rotate rapidly can be very loud. Accordingly, ensuring designs do not overheat while keeping fan noise below acceptable noise limits has long been an area of intense research.

Examples disclosed herein set forth improved techniques for fan control. Examples disclosed herein better meet user expectations: users often expect low noise levels at low ambient temperature but will tolerate higher noise levels at a relatively higher ambient temperatures. In some examples, a system on a chip (SoC) thermal setpoint is determined based on a temperature that is ambient to the SoC (e.g., a GPU, an infrastructure processing unit (IPU), a neural network processor, etc.). For example, if an ambient temperature is below a threshold value, a low SOC thermal setpoint may be selected. Above the threshold value, a high SOC temperature setpoint may be selected. Some examples further include parameters to adjust a guard-band (e.g., a gap band) temperature threshold to prevent acoustic fluctuations due to small ambient fluctuations around the threshold. Examples disclosed herein may modulate a fan to cause programmable circuitry (e.g., a GPU, an infrastructure processing unit (IPU), a CPU, etc.) to satisfy the thermal threshold.

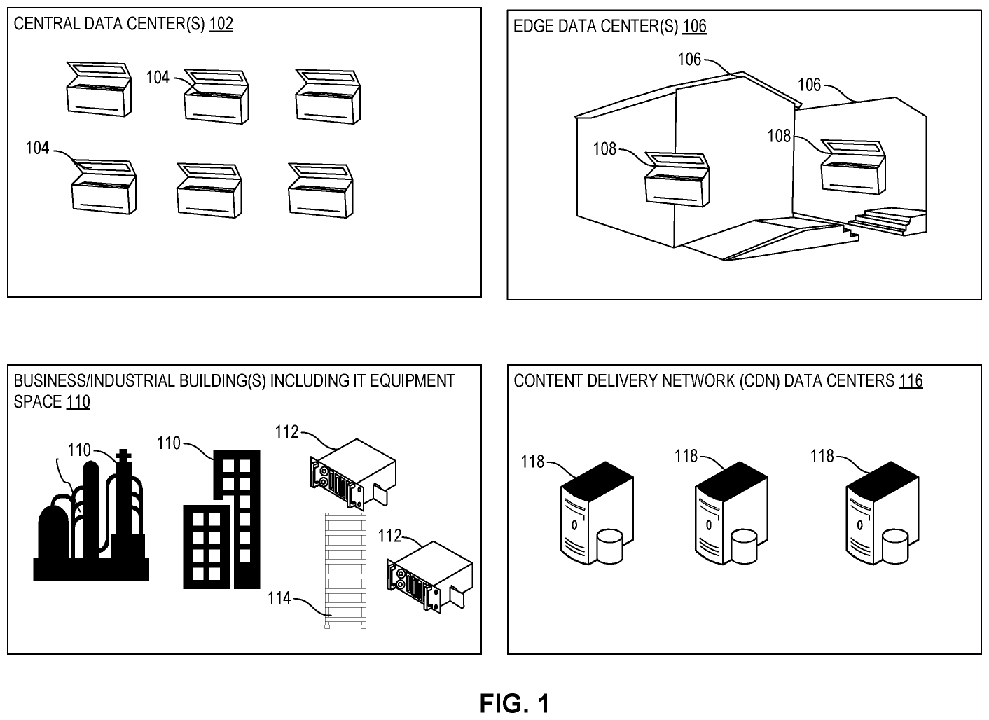

Turning to the figures, FIG. 1 illustrates one or more example environments in which teachings of this disclosure may be implemented. The example environment(s) of FIG. 1 can include one or more central data centers 102. The central data center(s) 102 can store a large number of servers used by, for instance, one or more organizations for data processing, storage, etc. As illustrated in FIG. 1, the central data center(s) 102 include a plurality of immersion tank(s) 104 to facilitate cooling of the servers and/or other electronic components stored at the central data center(s) 102. The immersion tank(s) 104 can provide for single-phase cooling or two-phase cooling.

The example environments of FIG. 1 can be part of an edge computing system. For instance, the example environments of FIG. 1 can include edge data centers or micro-data centers 106. The edge data center(s) 106 can include, for example, data centers located at a base of a cell tower. In some examples, the edge data center(s) 106 are located at or near a top of a cell tower and/or other utility pole. The edge data center(s) 106 include respective housings that store server(s), where the server(s) can be in communication with, for instance, the server(s) stored at the central data center(s) 102, client devices, and/or other computing devices in the edge network. Example housings of the edge data center(s) 106 may include materials that form one or more exterior surfaces that partially or fully protect contents therein, in which protection may include weather protection, hazardous environment protection (e.g., EMI, vibration, extreme temperatures), and/or enable submergibility. Example housings may include power circuitry to provide power for stationary and/or portable implementations, such as AC power inputs, DC power inputs, AC/DC or DC/AC converter(s), power regulators, transformers, charging circuitry, batteries, wired inputs and/or wireless power inputs. As illustrated in FIG. 1, the edge data center(s) 106 can include immersion tank(s) 108 to store server(s) and/or other electronic component(s) located at the edge data center(s) 106.

The example environment(s) of FIG. 1 can include buildings 110 for purposes of business and/or industry that store information technology (IT) equipment in, for example, one or more rooms of the building(s) 110. For example, as represented in FIG. 1, server(s) 112 can be stored with server rack(s) 114 that support the server(s) 112 (e.g., in an opening of slot of the rack 114). In some examples, the server(s) 112 located at the buildings 110 include on-premise server(s) of an edge computing network, where the on-premise server(s) are in communication with remote server(s) (e.g., the server(s) at the edge data center(s) 106) and/or other computing device(s) within an edge network.

The example environment(s) of FIG. 1 include content delivery network (CDN) data center(s) 116. The CDN data center(s) 116 of this example include server(s) 118 that cache content such as images, webpages, videos, etc. accessed via user devices. The server(s) 118 of the CDN data centers 116 can be disposed in immersion cooling tank(s) such as the immersion tanks 104, 108 shown in connection with the data centers 102, 106.

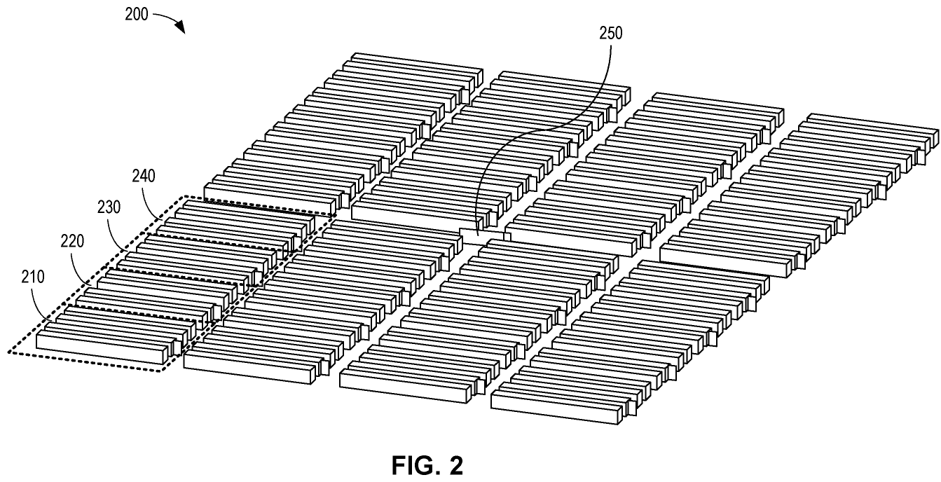

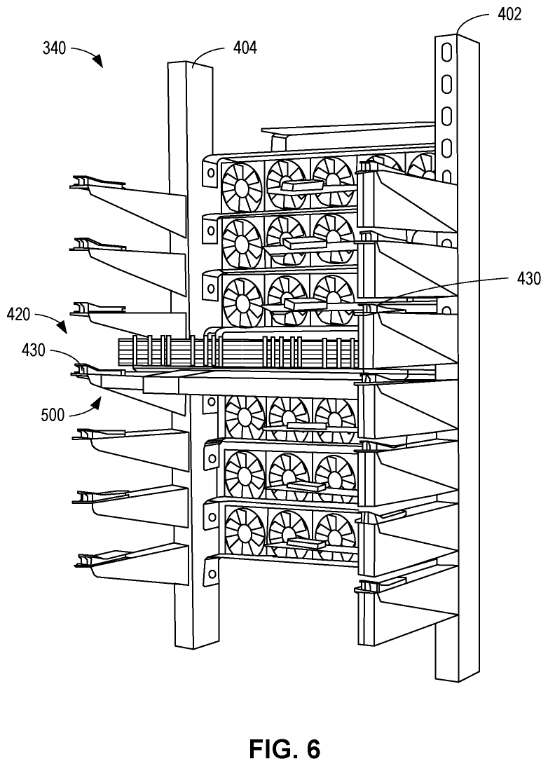

In some instances, the example data centers 102, 106, 116 and/or building(s) 110 of FIG. 1 include servers and/or other electronic components that are cooled independent of immersion tanks (e.g., the immersion tanks 104, 108) and/or an associated immersion cooling system. That is, in some examples, some or all of the servers and/or other electronic components in the data centers 102, 106, 116 and/or building(s) 110 can be cooled by air and/or liquid coolants without immersing the servers and/or other electronic components therein. Thus, in some examples, the immersion tanks 104, 108 of FIG. 1 may be omitted. Further, the example data centers 102, 106, 116 and/or building(s) 110 of FIG. 1 can correspond to, be implemented by, and/or be adaptations of the example data center 200 described in further detail below in connection with FIGS. 2-16.

Although a certain number of cooling tank(s) and other component(s) are shown in the figures, any number of such components may be present. Also, the example cooling data centers and/or other structures or environments disclosed herein are not limited to arrangements of the size that are depicted in FIG. 1. For instance, the structures containing example cooling systems and/or components thereof disclosed herein can be of a size that includes an opening to accommodate service personnel, such as the example data center(s) 106 of FIG. 1, but can also be smaller (e.g., a “doghouse” enclosure). For instance, the structures containing example cooling systems and/or components thereof disclosed herein can be sized such that access (e.g., the only access) to an interior of the structure is a port for service personnel to reach into the structure. In some examples, the structures containing example cooling systems and/or components thereof disclosed herein are be sized such that only a tool can reach into the enclosure because the structure may be supported by, for a utility pole or radio tower, or a larger structure.

In addition to or as an alternative to the immersion tanks 104, 108, any of the example environments of FIG. 1 can utilize one or more liquid cooling systems having a cold plate to control the temperature of the electronic devices/components in the example environments.

FIG. 2 illustrates an example data center 200 in which disaggregated resources may cooperatively execute one or more workloads (e.g., applications on behalf of customers). The illustrated data center 200 includes multiple platforms 210, 220, 230, 240 (referred to herein as pods), each of which includes one or more rows of racks. Although the data center 200 is shown with multiple pods, in some examples, the data center 200 may be implemented as a single pod. As described in more detail herein, a rack may house multiple sleds. A sled may be primarily equipped with a particular type of resource (e.g., memory devices, data storage devices, accelerator devices, general purpose processors), i.e., resources that can be logically coupled to form a composed node. Some such nodes may act as, for example, a server. In the illustrative example, the sleds in the pods 210, 220, 230, 240 are connected to multiple pod switches (e.g., switches that route data communications to and from sleds within the pod). The pod switches, in turn, connect with spine switches 250 that switch communications among pods (e.g., the pods 210, 220, 230, 240) in the data center 200. In some examples, the sleds may be connected with a fabric using Intel Omni-Path™ technology. In other examples, the sleds may be connected with other fabrics, such as InfiniBand or Ethernet. As described in more detail herein, resources within the sleds in the data center 200 may be allocated to a group (referred to herein as a “managed node”) containing resources from one or more sleds to be collectively utilized in the execution of a workload. The workload can execute as if the resources belonging to the managed node were located on the same sled. The resources in a managed node may belong to sleds belonging to different racks, and even to different pods 210, 220, 230, 240. As such, some resources of a single sled may be allocated to one managed node while other resources of the same sled are allocated to a different managed node (e.g., first processor circuitry assigned to one managed node and second processor circuitry of the same sled assigned to a different managed node).

A data center including disaggregated resources, such as the data center 200, can be used in a wide variety of contexts, such as enterprise, government, cloud service provider, and communications service provider (e.g., Telco's), as well in a wide variety of sizes, from cloud service provider mega-data centers that consume over 200,000 sq. ft. to single- or multi-rack installations for use in base stations.

In some examples, the disaggregation of resources is accomplished by using individual sleds that include predominantly a single type of resource (e.g., compute sleds including primarily compute resources, memory sleds including primarily memory resources). The disaggregation of resources in this manner, and the selective allocation and deallocation of the disaggregated resources to form a managed node assigned to execute a workload, improves the operation and resource usage of the data center 200 relative to typical data centers. Such typical data centers include hyperconverged servers containing compute, memory, storage, and perhaps additional resources in a single chassis. For example, because a given sled will contain mostly resources of a same particular type, resources of that type can be upgraded independently of other resources. Additionally, because different resource types (processors, storage, accelerators, etc.) typically have different refresh rates, greater resource utilization and reduced total cost of ownership may be achieved. For example, a data center operator can upgrade the processor circuitry throughout a facility by only swapping out the compute sleds. In such a case, accelerator and storage resources may not be contemporaneously upgraded and, rather, may be allowed to continue operating until those resources are scheduled for their own refresh. Resource utilization may also increase. For example, if managed nodes are composed based on requirements of the workloads that will be running on them, resources within a node are more likely to be fully utilized. Such utilization may allow for more managed nodes to run in a data center with a given set of resources, or for a data center expected to run a given set of workloads, to be built using fewer resources.

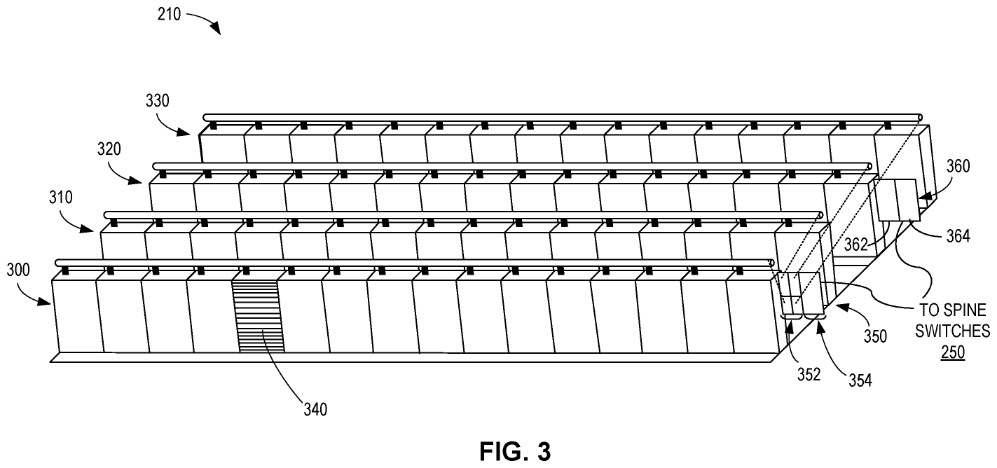

Referring now to FIG. 3, the pod 210, in the illustrative example, includes a set of rows 300, 310, 320, 330 of racks 340. Individual ones of the racks 340 may house multiple sleds (e.g., sixteen sleds) and provide power and data connections to the housed sleds, as described in more detail herein. In the illustrative example, the racks are connected to multiple pod switches 350, 360. The pod switch 350 includes a set of ports 352 to which the sleds of the racks of the pod 210 are connected and another set of ports 354 that connect the pod 210 to the spine switches 250 to provide connectivity to other pods in the data center 200. Similarly, the pod switch 360 includes a set of ports 362 to which the sleds of the racks of the pod 210 are connected and a set of ports 364 that connect the pod 210 to the spine switches 250. As such, the use of the pair of switches 350, 360 provides an amount of redundancy to the pod 210. For example, if either of the switches 350, 360 fails, the sleds in the pod 210 may still maintain data communication with the remainder of the data center 200 (e.g., sleds of other pods) through the other switch 350, 360. Furthermore, in the illustrative example, the switches 250, 350, 360 may be implemented as dual-mode optical switches, capable of routing both Ethernet protocol communications carrying Internet Protocol (IP) packets and communications according to a second, high-performance link-layer protocol (e.g., PCI Express) via optical signaling media of an optical fabric.

It should be appreciated that any one of the other pods 220, 230, 240 (as well as any additional pods of the data center 200) may be similarly structured as, and have components similar to, the pod 210 shown in and disclosed in regard to FIG. 3 (e.g., a given pod may have rows of racks housing multiple sleds as described above). Additionally, while two pod switches 350, 360 are shown, it should be understood that in other examples, a different number of pod switches may be present, providing even more failover capacity. In other examples, pods may be arranged differently than the rows-of-racks configuration shown in FIGS. 2 and 3. For example, a pod may include multiple sets of racks arranged radially, i.e., the racks are equidistant from a center switch.

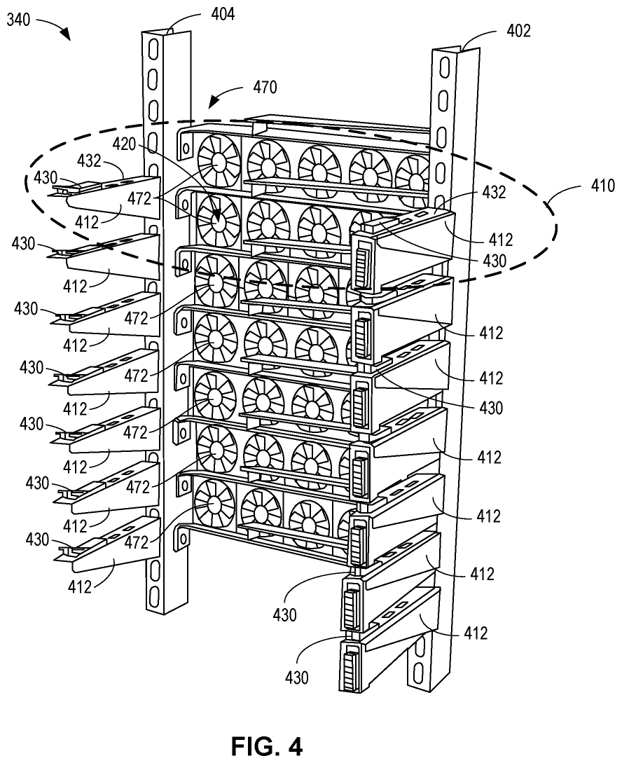

FIGS. 4-6 illustrate an example rack 340 of the data center 200. As shown in the illustrated example, the rack 340 includes two elongated support posts 402, 404, which are arranged vertically. For example, the elongated support posts 402, 404 may extend upwardly from a floor of the data center 200 when deployed. The rack 340 also includes one or more horizontal pairs 410 of elongated support arms 412 (identified in FIG. 4 via a dashed ellipse) configured to support a sled of the data center 200 as discussed below. One elongated support arm 412 of the pair of elongated support arms 412 extends outwardly from the elongated support post 402 and the other elongated support arm 412 extends outwardly from the elongated support post 404.

In the illustrative examples, at least some of the sleds of the data center 200 are chassis-less sleds. That is, such sleds have a chassis-less circuit board substrate on which physical resources (e.g., processors, memory, accelerators, storage, etc.) are mounted as discussed in more detail below. As such, the rack 340 is configured to receive the chassis-less sleds. For example, a given pair 410 of the elongated support arms 412 defines a sled slot 420 of the rack 340, which is configured to receive a corresponding chassis-less sled. To do so, the elongated support arms 412 include corresponding circuit board guides 430 configured to receive the chassis-less circuit board substrate of the sled. The circuit board guides 430 are secured to, or otherwise mounted to, a top side 432 of the corresponding elongated support arms 412. For example, in the illustrative example, the circuit board guides 430 are mounted at a distal end of the corresponding elongated support arm 412 relative to the corresponding elongated support post 402, 404. For clarity of FIGS. 4-6, not every circuit board guide 430 may be referenced in each figure. In some examples, at least some of the sleds include a chassis and the racks 340 are suitably adapted to receive the chassis.

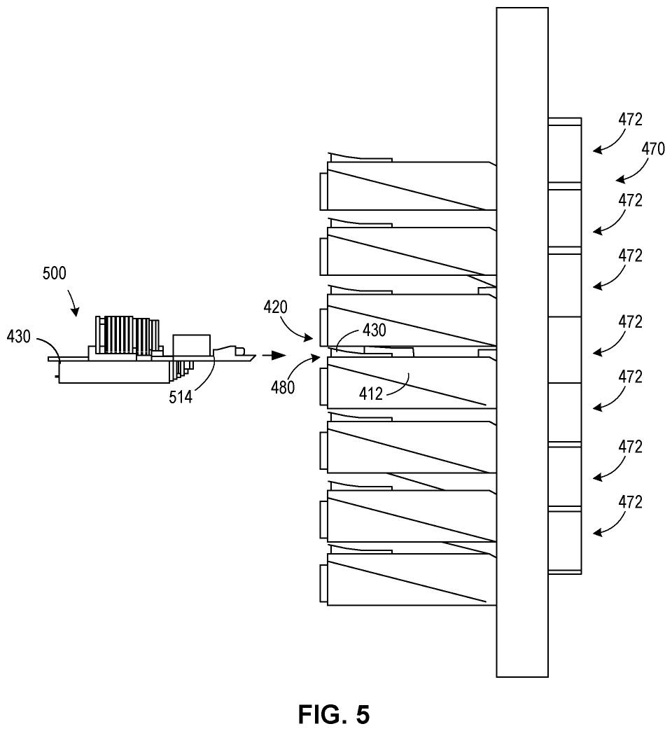

The circuit board guides 430 include an inner wall that defines a circuit board slot 480 configured to receive the chassis-less circuit board substrate of a sled 500 when the sled 500 is received in the corresponding sled slot 420 of the rack 340. To do so, as shown in FIG. 5, a user (or robot) aligns the chassis-less circuit board substrate of an illustrative chassis-less sled 500 to a sled slot 420. The user, or robot, may then slide the chassis-less circuit board substrate forward into the sled slot 420 such that each side edge 514 of the chassis-less circuit board substrate is received in a corresponding circuit board slot 480 of the circuit board guides 430 of the pair 410 of elongated support arms 412 that define the corresponding sled slot 420 as shown in FIG. 5. By having robotically accessible and robotically manipulable sleds including disaggregated resources, the different types of resource can be upgraded independently of one other and at their own optimized refresh rate. Furthermore, the sleds are configured to blindly mate with power and data communication cables in the rack 340, enhancing their ability to be quickly removed, upgraded, reinstalled, and/or replaced. As such, in some examples, the data center 200 may operate (e.g., execute workloads, undergo maintenance and/or upgrades, etc.) without human involvement on the data center floor. In other examples, a human may facilitate one or more maintenance or upgrade operations in the data center 200.

It should be appreciated that the circuit board guides 430 are dual sided. That is, a circuit board guide 430 includes an inner wall that defines a circuit board slot 480 on each side of the circuit board guide 430. In this way, the circuit board guide 430 can support a chassis-less circuit board substrate on either side. As such, a single additional elongated support post may be added to the rack 340 to turn the rack 340 into a two-rack solution that can hold twice as many sled slots 420 as shown in FIG. 4. The illustrative rack 340 includes seven pairs 410 of elongated support arms 412 that define seven corresponding sled slots 420. The sled slots 420 are configured to receive and support a corresponding sled 500 as discussed above. In other examples, the rack 340 may include additional or fewer pairs 410 of elongated support arms 412 (i.e., additional, or fewer sled slots 420). It should be appreciated that because the sled 500 is chassis-less, the sled 500 may have an overall height that is different than typical servers. As such, in some examples, the height of a given sled slot 420 may be shorter than the height of a typical server (e.g., shorter than a single rank unit, referred to as “1 U”). That is, the vertical distance between pairs 410 of elongated support arms 412 may be less than a standard rack unit “1 U.” Additionally, due to the relative decrease in height of the sled slots 420, the overall height of the rack 340 in some examples may be shorter than the height of traditional rack enclosures. For example, in some examples, the elongated support posts 402, 404 may have a length of six feet or less. Again, in other examples, the rack 340 may have different dimensions. For example, in some examples, the vertical distance between pairs 410 of elongated support arms 412 may be greater than a standard rack unit “1 U”. In such examples, the increased vertical distance between the sleds allows for larger heatsinks to be attached to the physical resources and for larger fans to be used (e.g., in the fan array 470 described below) for cooling the sleds, which in turn can allow the physical resources to operate at increased power levels. Further, it should be appreciated that the rack 340 does not include any walls, enclosures, or the like. Rather, the rack 340 is an enclosure-less rack that is opened to the local environment. In some cases, an end plate may be attached to one of the elongated support posts 402, 404 in those situations in which the rack 340 forms an end-of-row rack in the data center 200.

In some examples, various interconnects may be routed upwardly or downwardly through the elongated support posts 402, 404. To facilitate such routing, the elongated support posts 402, 404 include an inner wall that defines an inner chamber in which interconnects may be located. The interconnects routed through the elongated support posts 402, 404 may be implemented as any type of interconnects including, but not limited to, data or communication interconnects to provide communication connections to the sled slots 420, power interconnects to provide power to the sled slots 420, and/or other types of interconnects.

The rack 340, in the illustrative example, includes a support platform on which a corresponding optical data connector (not shown) is mounted. Such optical data connectors are associated with corresponding sled slots 420 and are configured to mate with optical data connectors of corresponding sleds 500 when the sleds 500 are received in the corresponding sled slots 420. In some examples, optical connections between components (e.g., sleds, racks, and switches) in the data center 200 are made with a blind mate optical connection. For example, a door on a given cable may prevent dust from contaminating the fiber inside the cable. In the process of connecting to a blind mate optical connector mechanism, the door is pushed open when the end of the cable approaches or enters the connector mechanism. Subsequently, the optical fiber inside the cable may enter a gel within the connector mechanism and the optical fiber of one cable comes into contact with the optical fiber of another cable within the gel inside the connector mechanism.

The illustrative rack 340 also includes a fan array 470 coupled to the cross-support arms of the rack 340. The fan array 470 includes one or more rows of cooling fans 472, which are aligned in a horizontal line between the elongated support posts 402, 404. In the illustrative example, the fan array 470 includes a row of cooling fans 472 for the different sled slots 420 of the rack 340. As discussed above, the sleds 500 do not include any on-board cooling system in the illustrative example and, as such, the fan array 470 provides cooling for such sleds 500 received in the rack 340. In other examples, some or all of the sleds 500 can include on-board cooling systems. Further, in some examples, the sleds 500 and/or the racks 340 may include and/or incorporate a liquid and/or immersion cooling system to facilitate cooling of electronic component(s) on the sleds 500. The rack 340, in the illustrative example, also includes different power supplies associated with different ones of the sled slots 420. A given power supply is secured to one of the elongated support arms 412 of the pair 410 of elongated support arms 412 that define the corresponding sled slot 420. For example, the rack 340 may include a power supply coupled or secured to individual ones of the elongated support arms 412 extending from the elongated support post 402. A given power supply includes a power connector configured to mate with a power connector of a sled 500 when the sled 500 is received in the corresponding sled slot 420. In the illustrative example, the sled 500 does not include any on-board power supply and, as such, the power supplies provided in the rack 340 supply power to corresponding sleds 500 when mounted to the rack 340. A given power supply is configured to satisfy the power requirements for its associated sled, which can differ from sled to sled. Additionally, the power supplies provided in the rack 340 can operate independent of each other. That is, within a single rack, a first power supply providing power to a compute sled can provide power levels that are different than power levels supplied by a second power supply providing power to an accelerator sled. The power supplies may be controllable at the sled level or rack level, and may be controlled locally by components on the associated sled or remotely, such as by another sled or an orchestrator.

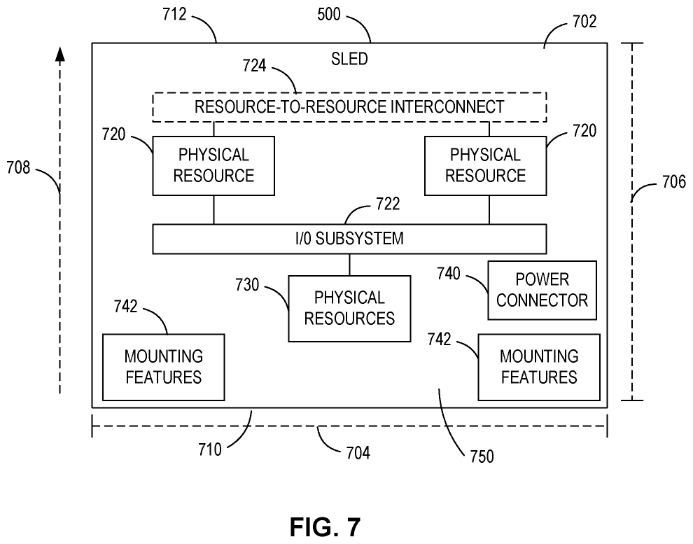

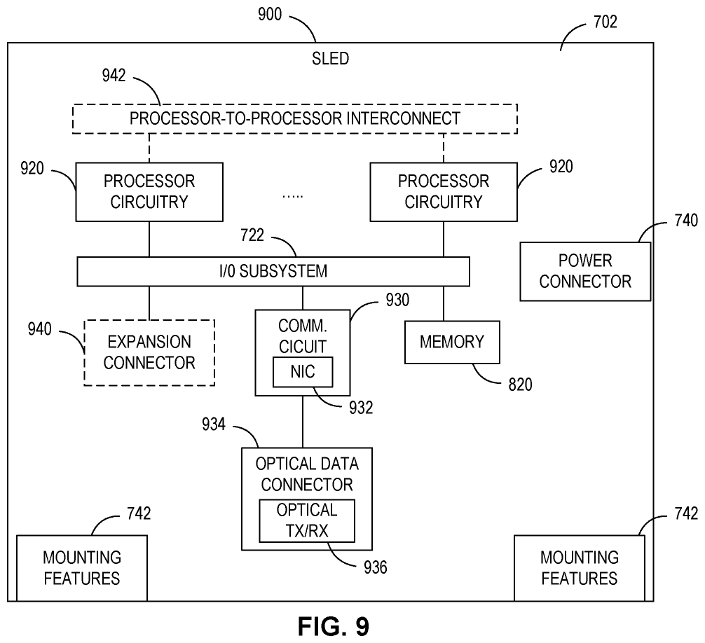

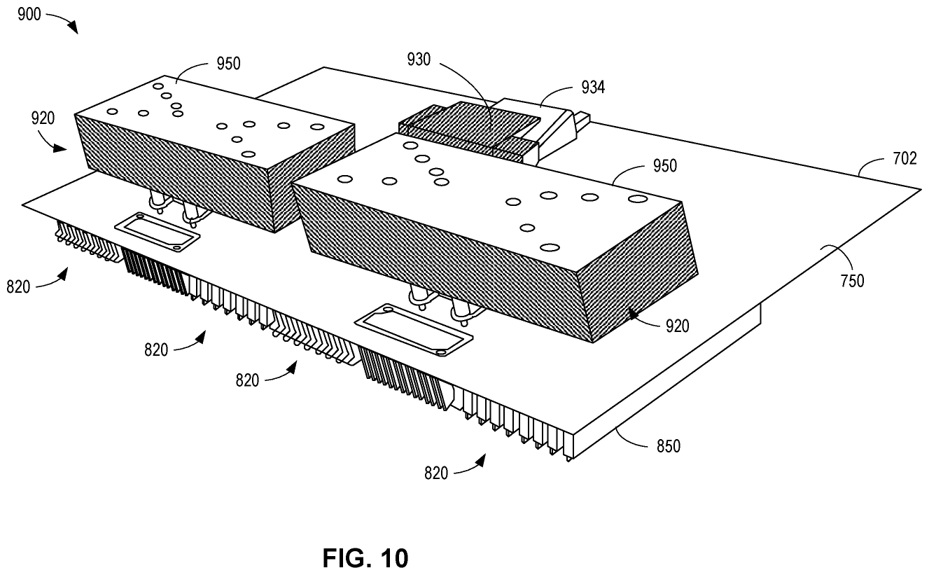

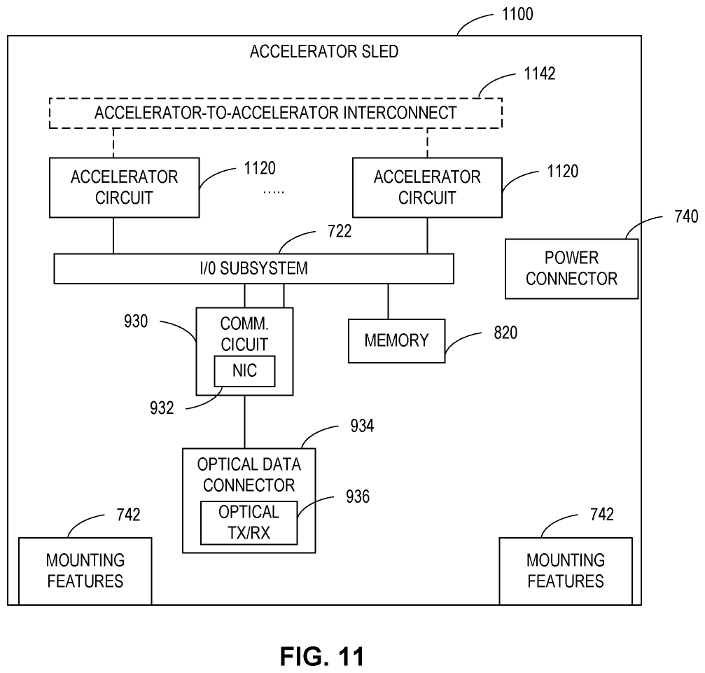

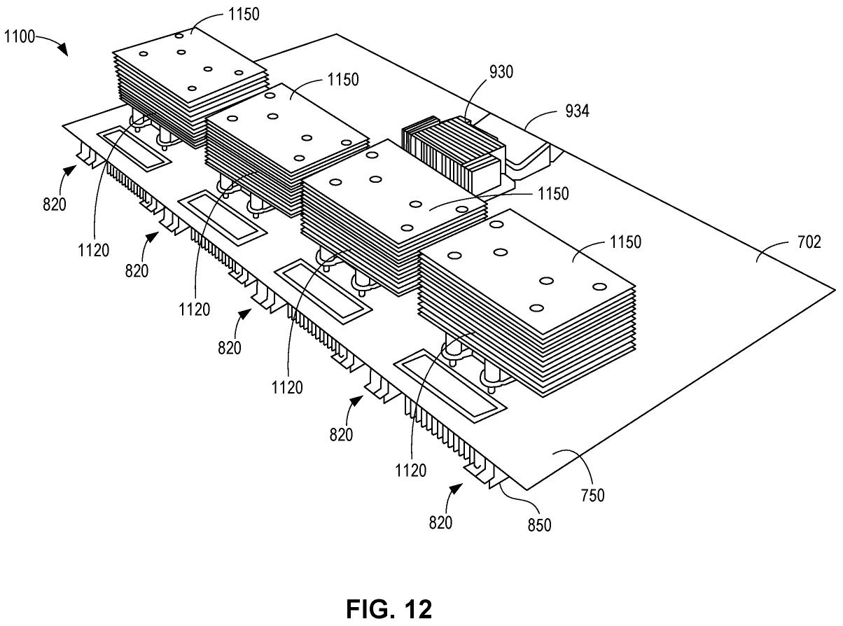

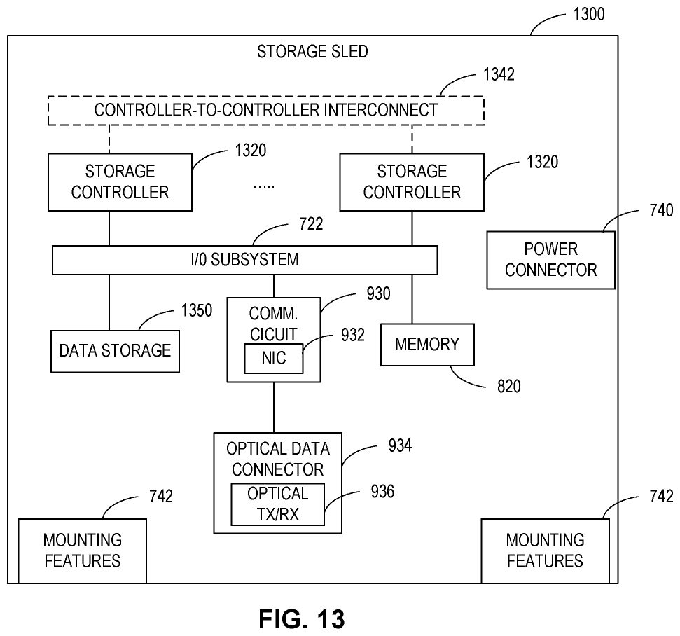

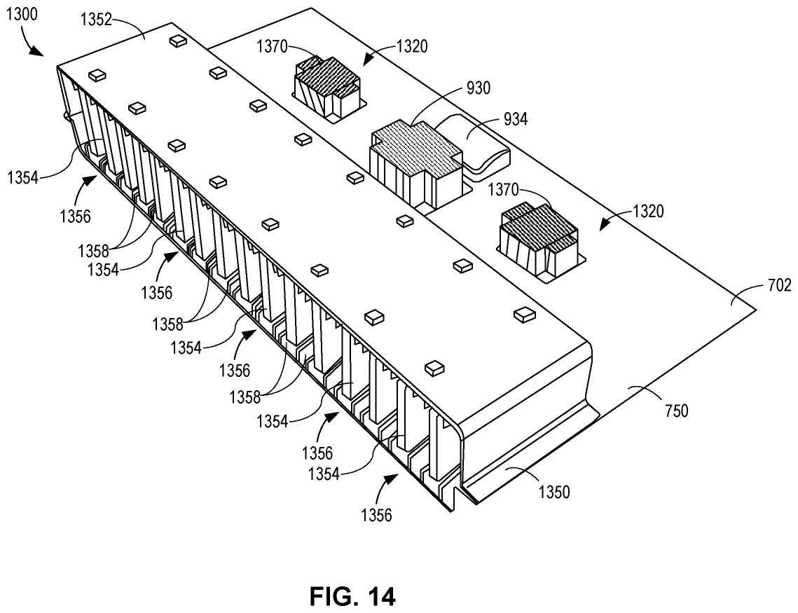

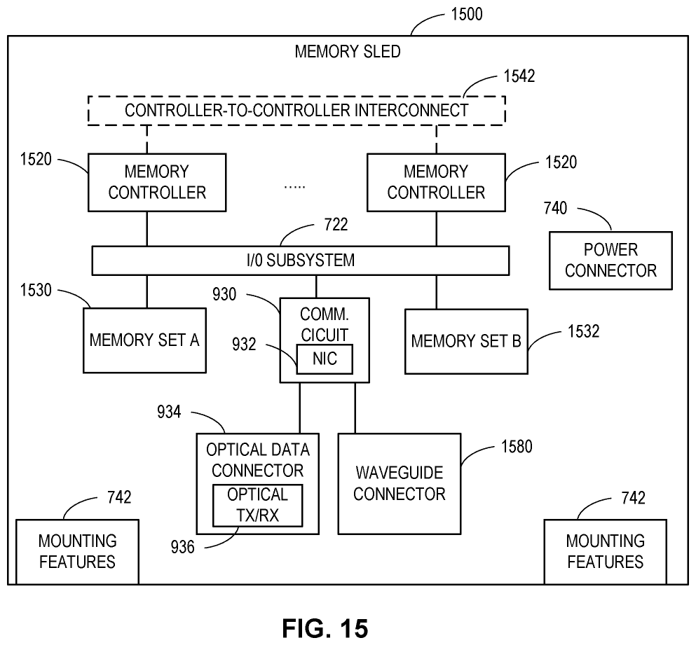

Referring now to FIG. 7, the sled 500, in the illustrative example, is configured to be mounted in a corresponding rack 340 of the data center 200 as discussed above. In some examples, a give sled 500 may be optimized or otherwise configured for performing particular tasks, such as compute tasks, acceleration tasks, data storage tasks, etc. For example, the sled 500 may be implemented as a compute sled 900 as discussed below in regard to FIGS. 9 and 10, an accelerator sled 1100 as discussed below in regard to FIGS. 11 and 12, a storage sled 1300 as discussed below in regard to FIGS. 13 and 14, or as a sled optimized or otherwise configured to perform other specialized tasks, such as a memory sled 1500, discussed below in regard to FIG. 15.

As discussed above, the illustrative sled 500 includes a chassis-less circuit board substrate 702, which supports various physical resources (e.g., electrical components) mounted thereon. It should be appreciated that the circuit board substrate 702 is “chassis-less” in that the sled 500 does not include a housing or enclosure. Rather, the chassis-less circuit board substrate 702 is open to the local environment. The chassis-less circuit board substrate 702 may be formed from any material capable of supporting the various electrical components mounted thereon. For example, in an illustrative example, the chassis-less circuit board substrate 702 is formed from an FR-4 glass-reinforced epoxy laminate material. Other materials may be used to form the chassis-less circuit board substrate 702 in other examples.

As discussed in more detail below, the chassis-less circuit board substrate 702 includes multiple features that improve the thermal cooling characteristics of the various electrical components mounted on the chassis-less circuit board substrate 702. As discussed, the chassis-less circuit board substrate 702 does not include a housing or enclosure, which may improve the airflow over the electrical components of the sled 500 by reducing those structures that may inhibit air flow. For example, because the chassis-less circuit board substrate 702 is not positioned in an individual housing or enclosure, there is no vertically-arranged backplane (e.g., a back plate of the chassis) attached to the chassis-less circuit board substrate 702, which could inhibit air flow across the electrical components. Additionally, the chassis-less circuit board substrate 702 has a geometric shape configured to reduce the length of the airflow path across the electrical components mounted to the chassis-less circuit board substrate 702. For example, the illustrative chassis-less circuit board substrate 702 has a width 704 that is greater than a depth 706 of the chassis-less circuit board substrate 702. In one particular example, the chassis-less circuit board substrate 702 has a width of about 21 inches and a depth of about 9 inches, compared to a typical server that has a width of about 17 inches and a depth of about 39 inches. As such, an airflow path 708 that extends from a front edge 710 of the chassis-less circuit board substrate 702 toward a rear edge 712 has a shorter distance relative to typical servers, which may improve the thermal cooling characteristics of the sled 500. Furthermore, although not illustrated in FIG. 7, the various physical resources mounted to the chassis-less circuit board substrate 702 in this example are mounted in corresponding locations such that no two substantively heat-producing electrical components shadow each other as discussed in more detail below. That is, no two electrical components, which produce appreciable heat during operation (i.e., greater than a nominal heat sufficient enough to adversely impact the cooling of another electrical component), are mounted to the chassis-less circuit board substrate 702 linearly in-line with each other along the direction of the airflow path 708 (i.e., along a direction extending from the front edge 710 toward the rear edge 712 of the chassis-less circuit board substrate 702). The placement and/or structure of the features may be suitable adapted when the electrical component(s) are being cooled via liquid (e.g., one phase or two phase cooling).

As discussed above, the illustrative sled 500 includes one or more physical resources 720 mounted to a top side 750 of the chassis-less circuit board substrate 702. Although two physical resources 720 are shown in FIG. 7, it should be appreciated that the sled 500 may include one, two, or more physical resources 720 in other examples. The physical resources 720 may be implemented as any type of processor, controller, or other compute circuit capable of performing various tasks such as compute functions and/or controlling the functions of the sled 500 depending on, for example, the type or intended functionality of the sled 500. For example, as discussed in more detail below, the physical resources 720 may be implemented as high-performance processors in examples in which the sled 500 is implemented as a compute sled, as accelerator co-processors or circuits in examples in which the sled 500 is implemented as an accelerator sled, storage controllers in examples in which the sled 500 is implemented as a storage sled, or a set of memory devices in examples in which the sled 500 is implemented as a memory sled.

The sled 500 also includes one or more additional physical resources 730 mounted to the top side 750 of the chassis-less circuit board substrate 702. In the illustrative example, the additional physical resources include a network interface controller (NIC) as discussed in more detail below. Depending on the type and functionality of the sled 500, the physical resources 730 may include additional or other electrical components, circuits, and/or devices in other examples.

The physical resources 720 are communicatively coupled to the physical resources 730 via an input/output (I/O) subsystem 722. The I/O subsystem 722 may be implemented as circuitry and/or components to facilitate input/output operations with the physical resources 720, the physical resources 730, and/or other components of the sled 500. For example, the I/O subsystem 722 may be implemented as, or otherwise include, memory controller hubs, input/output control hubs, integrated sensor hubs, firmware devices, communication links (e.g., point-to-point links, bus links, wires, cables, waveguides, light guides, printed circuit board traces, etc.), and/or other components and subsystems to facilitate the input/output operations. In the illustrative example, the I/O subsystem 722 is implemented as, or otherwise includes, a double data rate 4 (DDR4) data bus or a DDR5 data bus.

In some examples, the sled 500 may also include a resource-to-resource interconnect 724. The resource-to-resource interconnect 724 may be implemented as any type of communication interconnect capable of facilitating resource-to-resource communications. In the illustrative example, the resource-to-resource interconnect 724 is implemented as a high-speed point-to-point interconnect (e.g., faster than the I/O subsystem 722). For example, the resource-to-resource interconnect 724 may be implemented as a QuickPath Interconnect (QPI), an UltraPath Interconnect (UPI), or other high-speed point-to-point interconnect dedicated to resource-to-resource communications.

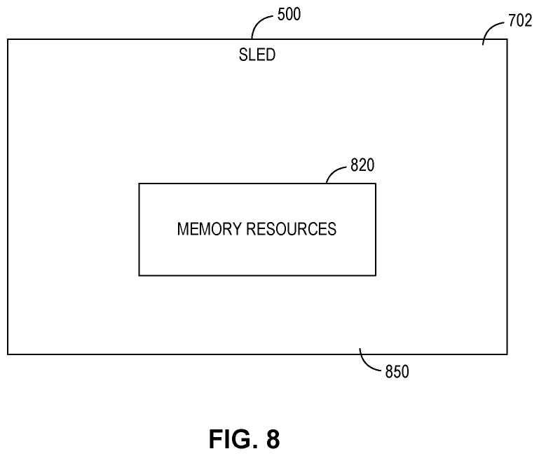

The sled 500 also includes a power connector 740 configured to mate with a corresponding power connector of the rack 340 when the sled 500 is mounted in the corresponding rack 340. The sled 500 receives power from a power supply of the rack 340 via the power connector 740 to supply power to the various electrical components of the sled 500. That is, the sled 500 does not include any local power supply (i.e., an on-board power supply) to provide power to the electrical components of the sled 500. The exclusion of a local or on-board power supply facilitates the reduction in the overall footprint of the chassis-less circuit board substrate 702, which may increase the thermal cooling characteristics of the various electrical components mounted on the chassis-less circuit board substrate 702 as discussed above. In some examples, voltage regulators are placed on a bottom side 850 (see FIG. 8) of the chassis-less circuit board substrate 702 directly opposite of processor circuitry 920 (see FIG. 9), and power is routed from the voltage regulators to the processor circuitry 920 by vias extending through the circuit board substrate 702. Such a configuration provides an increased thermal budget, additional current and/or voltage, and better voltage control relative to typical printed circuit boards in which processor power is delivered from a voltage regulator, in part, by printed circuit traces.

In some examples, the sled 500 may also include mounting features 742 configured to mate with a mounting arm, or other structure, of a robot to facilitate the placement of the sled 700 in a rack 340 by the robot. The mounting features 742 may be implemented as any type of physical structures that allow the robot to grasp the sled 500 without damaging the chassis-less circuit board substrate 702 or the electrical components mounted thereto. For example, in some examples, the mounting features 742 may be implemented as non-conductive pads attached to the chassis-less circuit board substrate 702. In other examples, the mounting features may be implemented as brackets, braces, or other similar structures attached to the chassis-less circuit board substrate 702. The particular number, shape, size, and/or make-up of the mounting feature 742 may depend on the design of the robot configured to manage the sled 500.

Referring now to FIG. 8, in addition to the physical resources 730 mounted on the top side 750 of the chassis-less circuit board substrate 702, the sled 500 also includes one or more memory devices 820 mounted to a bottom side 850 of the chassis-less circuit board substrate 702. That is, the chassis-less circuit board substrate 702 is implemented as a double-sided circuit board. The physical resources 720 are communicatively coupled to the memory devices 820 via the I/O subsystem 722. For example, the physical resources 720 and the memory devices 820 may be communicatively coupled by one or more vias extending through the chassis-less circuit board substrate 702. Different ones of the physical resources 720 may be communicatively coupled to different sets of one or more memory devices 820 in some examples. Alternatively, in other examples, different ones of the physical resources 720 may be communicatively coupled to the same ones of the memory devices 820.

The memory devices 820 may be implemented as any type of memory device capable of storing data for the physical resources 720 during operation of the sled 500, such as any type of volatile (e.g., dynamic random access memory (DRAM), etc.) or non-volatile memory. Volatile memory may be a storage medium that requires power to maintain the state of data stored by the medium. Non-limiting examples of volatile memory may include various types of random access memory (RAM), such as dynamic random access memory (DRAM) or static random access memory (SRAM). One particular type of DRAM that may be used in a memory module is synchronous dynamic random access memory (SDRAM). In particular examples, DRAM of a memory component may comply with a standard promulgated by JEDEC, such as JESD79F for DDR SDRAM, JESD79-2F for DDR2 SDRAM, JESD79-3F for DDR3 SDRAM, JESD79-4A for DDR4 SDRAM, JESD209 for Low Power DDR (LPDDR), JESD209-2 for LPDDR2, JESD209-3 for LPDDR3, and JESD209-4 for LPDDR4. Such standards (and similar standards) may be referred to as DDR-based standards and communication interfaces of the storage devices that implement such standards may be referred to as DDR-based interfaces.

In one example, the memory device is a block addressable memory device, such as those based on NAND or NOR technologies. A memory device may also include next-generation nonvolatile devices, such as Intel 3D XPoint™ memory or other byte addressable write-in-place nonvolatile memory devices. In one example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory. The memory device may refer to the die itself and/or to a packaged memory product. In some examples, the memory device may include a transistor-less stackable cross point architecture in which memory cells sit at the intersection of word lines and bit lines and are individually addressable and in which bit storage is based on a change in bulk resistance.

Referring now to FIG. 9, in some examples, the sled 500 may be implemented as a compute sled 900. The compute sled 900 is optimized, or otherwise configured, to perform compute tasks. As discussed above, the compute sled 900 may rely on other sleds, such as acceleration sleds and/or storage sleds, to perform such compute tasks. The compute sled 900 includes various physical resources (e.g., electrical components) similar to the physical resources of the sled 500, which have been identified in FIG. 9 using the same reference numbers. The description of such components provided above in regard to FIGS. 7 and 8 applies to the corresponding components of the compute sled 900 and is not repeated herein for clarity of the description of the compute sled 900.

In the illustrative compute sled 900, the physical resources 720 include processor circuitry 920. Although only two blocks of processor circuitry 920 are shown in FIG. 9, it should be appreciated that the compute sled 900 may include additional processor circuits 920 in other examples. Illustratively, the processor circuitry 920 corresponds to high-performance processors 920 and may be configured to operate at a relatively high power rating. Although the high-performance processor circuitry 920 generates additional heat operating at power ratings greater than typical processors (which operate at around 155-230 W), the enhanced thermal cooling characteristics of the chassis-less circuit board substrate 702 discussed above facilitate the higher power operation. For example, in the illustrative example, the processor circuitry 920 is configured to operate at a power rating of at least 250 W. In some examples, the processor circuitry 920 may be configured to operate at a power rating of at least 350 W.

In some examples, the compute sled 900 may also include a processor-to-processor interconnect 942. Similar to the resource-to-resource interconnect 724 of the sled 500 discussed above, the processor-to-processor interconnect 942 may be implemented as any type of communication interconnect capable of facilitating processor-to-processor interconnect 942 communications. In the illustrative example, the processor-to-processor interconnect 942 is implemented as a high-speed point-to-point interconnect (e.g., faster than the I/O subsystem 722). For example, the processor-to-processor interconnect 942 may be implemented as a QuickPath Interconnect (QPI), an UltraPath Interconnect (UPI), or other high-speed point-to-point interconnect dedicated to processor-to-processor communications.

The compute sled 900 also includes a communication circuit 930. The illustrative communication circuit 930 includes a network interface controller (NIC) 932, which may also be referred to as a host fabric interface (HFI). The NIC 932 may be implemented as, or otherwise include, any type of integrated circuit, discrete circuits, controller chips, chipsets, add-in-boards, daughtercards, network interface cards, or other devices that may be used by the compute sled 900 to connect with another compute device (e.g., with other sleds 500). In some examples, the NIC 932 may be implemented as part of a system-on-a-chip (SoC) that includes one or more processors, or included on a multichip package that also contains one or more processors. In some examples, the NIC 932 may include a local processor (not shown) and/or a local memory (not shown) that are both local to the NIC 932. In such examples, the local processor of the NIC 932 may be capable of performing one or more of the functions of the processor circuitry 920. Additionally or alternatively, in such examples, the local memory of the NIC 932 may be integrated into one or more components of the compute sled at the board level, socket level, chip level, and/or other levels.

The communication circuit 930 is communicatively coupled to an optical data connector 934. The optical data connector 934 is configured to mate with a corresponding optical data connector of the rack 340 when the compute sled 900 is mounted in the rack 340. Illustratively, the optical data connector 934 includes a plurality of optical fibers which lead from a mating surface of the optical data connector 934 to an optical transceiver 936. The optical transceiver 936 is configured to convert incoming optical signals from the rack-side optical data connector to electrical signals and to convert electrical signals to outgoing optical signals to the rack-side optical data connector. Although shown as forming part of the optical data connector 934 in the illustrative example, the optical transceiver 936 may form a portion of the communication circuit 930 in other examples.

In some examples, the compute sled 900 may also include an expansion connector 940. In such examples, the expansion connector 940 is configured to mate with a corresponding connector of an expansion chassis-less circuit board substrate to provide additional physical resources to the compute sled 900. The additional physical resources may be used, for example, by the processor circuitry 920 during operation of the compute sled 900. The expansion chassis-less circuit board substrate may be substantially similar to the chassis-less circuit board substrate 702 discussed above and may include various electrical components mounted thereto. The particular electrical components mounted to the expansion chassis-less circuit board substrate may depend on the intended functionality of the expansion chassis-less circuit board substrate. For example, the expansion chassis-less circuit board substrate may provide additional compute resources, memory resources, and/or storage resources. As such, the additional physical resources of the expansion chassis-less circuit board substrate may include, but is not limited to, processors, memory devices, storage devices, and/or accelerator circuits including, for example, field programmable gate arrays (FPGA), application-specific integrated circuits (ASICs), security co-processors, graphics processing units (GPUs), machine learning circuits, or other specialized processors, controllers, devices, and/or circuits.

Referring now to FIG. 10, an illustrative example of the compute sled 900 is shown. As shown, the processor circuitry 920, communication circuit 930, and optical data connector 934 are mounted to the top side 750 of the chassis-less circuit board substrate 702. Any suitable attachment or mounting technology may be used to mount the physical resources of the compute sled 900 to the chassis-less circuit board substrate 702. For example, the various physical resources may be mounted in corresponding sockets (e.g., a processor socket), holders, or brackets. In some cases, some of the electrical components may be directly mounted to the chassis-less circuit board substrate 702 via soldering or similar techniques.

As discussed above, the separate processor circuitry 920 and the communication circuit 930 are mounted to the top side 750 of the chassis-less circuit board substrate 702 such that no two heat-producing, electrical components shadow each other. In the illustrative example, the processor circuitry 920 and the communication circuit 930 are mounted in corresponding locations on the top side 750 of the chassis-less circuit board substrate 702 such that no two of those physical resources are linearly in-line with others along the direction of the airflow path 708. It should be appreciated that, although the optical data connector 934 is in-line with the communication circuit 930, the optical data connector 934 produces no or nominal heat during operation.

The memory devices 820 of the compute sled 900 are mounted to the bottom side 850 of the of the chassis-less circuit board substrate 702 as discussed above in regard to the sled 500. Although mounted to the bottom side 850, the memory devices 820 are communicatively coupled to the processor circuitry 920 located on the top side 750 via the I/O subsystem 722. Because the chassis-less circuit board substrate 702 is implemented as a double-sided circuit board, the memory devices 820 and the processor circuitry 920 may be communicatively coupled by one or more vias, connectors, or other mechanisms extending through the chassis-less circuit board substrate 702. Different processor circuitry 920 (e.g., different processors) may be communicatively coupled to a different set of one or more memory devices 820 in some examples. Alternatively, in other examples, different processor circuitry 920 (e.g., different processors) may be communicatively coupled to the same ones of the memory devices 820. In some examples, the memory devices 820 may be mounted to one or more memory mezzanines on the bottom side of the chassis-less circuit board substrate 702 and may interconnect with a corresponding processor circuitry 920 through a ball-grid array.

Different processor circuitry 920 (e.g., different processors) include and/or is associated with corresponding heatsinks 950 secured thereto. Due to the mounting of the memory devices 820 to the bottom side 850 of the chassis-less circuit board substrate 702 (as well as the vertical spacing of the sleds 500 in the corresponding rack 340), the top side 750 of the chassis-less circuit board substrate 702 includes additional “free” area or space that facilitates the use of heatsinks 950 having a larger size relative to traditional heatsinks used in typical servers. Additionally, due to the improved thermal cooling characteristics of the chassis-less circuit board substrate 702, none of the processor heatsinks 950 include cooling fans attached thereto. That is, the heatsinks 950 may be fan-less heatsinks. In some examples, the heatsinks 950 mounted atop the processor circuitry 920 may overlap with the heatsink attached to the communication circuit 930 in the direction of the airflow path 708 due to their increased size, as illustratively suggested by FIG. 10.

Referring now to FIG. 11, in some examples, the sled 500 may be implemented as an accelerator sled 1100. The accelerator sled 1100 is configured, to perform specialized compute tasks, such as machine learning, encryption, hashing, or other computational-intensive task. In some examples, for example, a compute sled 900 may offload tasks to the accelerator sled 1100 during operation. The accelerator sled 1100 includes various components similar to components of the sled 500 and/or the compute sled 900, which have been identified in FIG. 11 using the same reference numbers. The description of such components provided above in regard to FIGS. 7, 8, and 9 apply to the corresponding components of the accelerator sled 1100 and is not repeated herein for clarity of the description of the accelerator sled 1100.

In the illustrative accelerator sled 1100, the physical resources 720 include accelerator circuits 1120. Although only two accelerator circuits 1120 are shown in FIG. 11, it should be appreciated that the accelerator sled 1100 may include additional accelerator circuits 1120 in other examples. For example, as shown in FIG. 12, the accelerator sled 1100 may include four accelerator circuits 1120. The accelerator circuits 1120 may be implemented as any type of processor, co-processor, compute circuit, or other device capable of performing compute or processing operations. For example, the accelerator circuits 1120 may be implemented as, for example, field programmable gate arrays (FPGA), application-specific integrated circuits (ASICs), security co-processors, graphics processing units (GPUs), neuromorphic processor units, quantum computers, machine learning circuits, or other specialized processors, controllers, devices, and/or circuits.

In some examples, the accelerator sled 1100 may also include an accelerator-to-accelerator interconnect 1142. Similar to the resource-to-resource interconnect 724 of the sled 700 discussed above, the accelerator-to-accelerator interconnect 1142 may be implemented as any type of communication interconnect capable of facilitating accelerator-to-accelerator communications. In the illustrative example, the accelerator-to-accelerator interconnect 1142 is implemented as a high-speed point-to-point interconnect (e.g., faster than the I/O subsystem 722). For example, the accelerator-to-accelerator interconnect 1142 may be implemented as a QuickPath Interconnect (QPI), an UltraPath Interconnect (UPI), or other high-speed point-to-point interconnect dedicated to processor-to-processor communications. In some examples, the accelerator circuits 1120 may be daisy-chained with a primary accelerator circuit 1120 connected to the NIC 932 and memory 820 through the I/O subsystem 722 and a secondary accelerator circuit 1120 connected to the NIC 932 and memory 820 through a primary accelerator circuit 1120.

Referring now to FIG. 12, an illustrative example of the accelerator sled 1100 is shown. As discussed above, the accelerator circuits 1120, the communication circuit 930, and the optical data connector 934 are mounted to the top side 750 of the chassis-less circuit board substrate 702. Again, the individual accelerator circuits 1120 and communication circuit 930 are mounted to the top side 750 of the chassis-less circuit board substrate 702 such that no two heat-producing, electrical components shadow each other as discussed above. The memory devices 820 of the accelerator sled 1100 are mounted to the bottom side 850 of the of the chassis-less circuit board substrate 702 as discussed above in regard to the sled 700. Although mounted to the bottom side 850, the memory devices 820 are communicatively coupled to the accelerator circuits 1120 located on the top side 750 via the I/O subsystem 722 (e.g., through vias). Further, the accelerator circuits 1120 may include and/or be associated with a heatsink 1150 that is larger than a traditional heatsink used in a server. As discussed above with reference to the heatsinks 950 of FIG. 9, the heatsinks 1150 may be larger than traditional heatsinks because of the “free” area provided by the memory resources 820 being located on the bottom side 850 of the chassis-less circuit board substrate 702 rather than on the top side 750.

Referring now to FIG. 13, in some examples, the sled 500 may be implemented as a storage sled 1300. The storage sled 1300 is configured, to store data in a data storage 1350 local to the storage sled 1300. For example, during operation, a compute sled 900 or an accelerator sled 1100 may store and retrieve data from the data storage 1350 of the storage sled 1300. The storage sled 1300 includes various components similar to components of the sled 500 and/or the compute sled 900, which have been identified in FIG. 13 using the same reference numbers. The description of such components provided above in regard to FIGS. 7, 8, and 9 apply to the corresponding components of the storage sled 1300 and is not repeated herein for clarity of the description of the storage sled 1300.

In the illustrative storage sled 1300, the physical resources 720 includes storage controllers 1320. Although only two storage controllers 1320 are shown in FIG. 13, it should be appreciated that the storage sled 1300 may include additional storage controllers 1320 in other examples. The storage controllers 1320 may be implemented as any type of processor, controller, or control circuit capable of controlling the storage and retrieval of data into the data storage 1350 based on requests received via the communication circuit 930. In the illustrative example, the storage controllers 1320 are implemented as relatively low-power processors or controllers. For example, in some examples, the storage controllers 1320 may be configured to operate at a power rating of about 75 watts.

In some examples, the storage sled 1300 may also include a controller-to-controller interconnect 1342. Similar to the resource-to-resource interconnect 724 of the sled 500 discussed above, the controller-to-controller interconnect 1342 may be implemented as any type of communication interconnect capable of facilitating controller-to-controller communications. In the illustrative example, the controller-to-controller interconnect 1342 is implemented as a high-speed point-to-point interconnect (e.g., faster than the I/O subsystem 722). For example, the controller-to-controller interconnect 1342 may be implemented as a QuickPath Interconnect (QPI), an UltraPath Interconnect (UPI), or other high-speed point-to-point interconnect dedicated to processor-to-processor communications.

Referring now to FIG. 14, an illustrative example of the storage sled 1300 is shown. In the illustrative example, the data storage 1350 is implemented as, or otherwise includes, a storage cage 1352 configured to house one or more solid state drives (SSDs) 1354. To do so, the storage cage 1352 includes a number of mounting slots 1356, which are configured to receive corresponding solid state drives 1354. The mounting slots 1356 include a number of drive guides 1358 that cooperate to define an access opening 1360 of the corresponding mounting slot 1356. The storage cage 1352 is secured to the chassis-less circuit board substrate 702 such that the access openings face away from (i.e., toward the front of) the chassis-less circuit board substrate 702. As such, solid state drives 1354 are accessible while the storage sled 1300 is mounted in a corresponding rack 304. For example, a solid state drive 1354 may be swapped out of a rack 340 (e.g., via a robot) while the storage sled 1300 remains mounted in the corresponding rack 340.

The storage cage 1352 illustratively includes sixteen mounting slots 1356 and is capable of mounting and storing sixteen solid state drives 1354. The storage cage 1352 may be configured to store additional or fewer solid state drives 1354 in other examples. Additionally, in the illustrative example, the solid state drives are mounted vertically in the storage cage 1352, but may be mounted in the storage cage 1352 in a different orientation in other examples. A given solid state drive 1354 may be implemented as any type of data storage device capable of storing long term data. To do so, the solid state drives 1354 may include volatile and non-volatile memory devices discussed above.

As shown in FIG. 14, the storage controllers 1320, the communication circuit 930, and the optical data connector 934 are illustratively mounted to the top side 750 of the chassis-less circuit board substrate 702. Again, as discussed above, any suitable attachment or mounting technology may be used to mount the electrical components of the storage sled 1300 to the chassis-less circuit board substrate 702 including, for example, sockets (e.g., a processor socket), holders, brackets, soldered connections, and/or other mounting or securing techniques.

As discussed above, the individual storage controllers 1320 and the communication circuit 930 are mounted to the top side 750 of the chassis-less circuit board substrate 702 such that no two heat-producing, electrical components shadow each other. For example, the storage controllers 1320 and the communication circuit 930 are mounted in corresponding locations on the top side 750 of the chassis-less circuit board substrate 702 such that no two of those electrical components are linearly in-line with each other along the direction of the airflow path 708.

The memory devices 820 (not shown in FIG. 14) of the storage sled 1300 are mounted to the bottom side 850 (not shown in FIG. 14) of the chassis-less circuit board substrate 702 as discussed above in regard to the sled 500. Although mounted to the bottom side 850, the memory devices 820 are communicatively coupled to the storage controllers 1320 located on the top side 750 via the I/O subsystem 722. Again, because the chassis-less circuit board substrate 702 is implemented as a double-sided circuit board, the memory devices 820 and the storage controllers 1320 may be communicatively coupled by one or more vias, connectors, or other mechanisms extending through the chassis-less circuit board substrate 702. The storage controllers 1320 include and/or are associated with a heatsink 1370 secured thereto. As discussed above, due to the improved thermal cooling characteristics of the chassis-less circuit board substrate 702 of the storage sled 1300, none of the heatsinks 1370 include cooling fans attached thereto. That is, the heatsinks 1370 may be fan-less heatsinks.

Referring now to FIG. 15, in some examples, the sled 500 may be implemented as a memory sled 1500. The storage sled 1500 is optimized, or otherwise configured, to provide other sleds 500 (e.g., compute sleds 900, accelerator sleds 1100, etc.) with access to a pool of memory (e.g., in two or more sets 1530, 1532 of memory devices 820) local to the memory sled 1300. For example, during operation, a compute sled 900 or an accelerator sled 1100 may remotely write to and/or read from one or more of the memory sets 1530, 1532 of the memory sled 1300 using a logical address space that maps to physical addresses in the memory sets 1530, 1532. The memory sled 1500 includes various components similar to components of the sled 500 and/or the compute sled 900, which have been identified in FIG. 15 using the same reference numbers. The description of such components provided above in regard to FIGS. 7, 8, and 9 apply to the corresponding components of the memory sled 1500 and is not repeated herein for clarity of the description of the memory sled 1500.

In the illustrative memory sled 1500, the physical resources 720 include memory controllers 1520. Although only two memory controllers 1520 are shown in FIG. 15, it should be appreciated that the memory sled 1500 may include additional memory controllers 1520 in other examples. The memory controllers 1520 may be implemented as any type of processor, controller, or control circuit capable of controlling the writing and reading of data into the memory sets 1530, 1532 based on requests received via the communication circuit 930. In the illustrative example, the memory controllers 1520 are connected to corresponding memory sets 1530, 1532 to write to and read from memory devices 820 (not shown) within the corresponding memory set 1530, 1532 and enforce any permissions (e.g., read, write, etc.) associated with sled 500 that has sent a request to the memory sled 1500 to perform a memory access operation (e.g., read or write).

In some examples, the memory sled 1500 may also include a controller-to-controller interconnect 1542. Similar to the resource-to-resource interconnect 724 of the sled 500 discussed above, the controller-to-controller interconnect 1542 may be implemented as any type of communication interconnect capable of facilitating controller-to-controller communications. In the illustrative example, the controller-to-controller interconnect 1542 is implemented as a high-speed point-to-point interconnect (e.g., faster than the I/O subsystem 722). For example, the controller-to-controller interconnect 1542 may be implemented as a QuickPath Interconnect (QPI), an UltraPath Interconnect (UPI), or other high-speed point-to-point interconnect dedicated to processor-to-processor communications. As such, in some examples, a memory controller 1520 may access, through the controller-to-controller interconnect 1542, memory that is within the memory set 1532 associated with another memory controller 1520. In some examples, a scalable memory controller is made of multiple smaller memory controllers, referred to herein as “chiplets,” on a memory sled (e.g., the memory sled 1500). The chiplets may be interconnected (e.g., using EMIB (Embedded Multi-Die Interconnect Bridge) technology). The combined chiplet memory controller may scale up to a relatively large number of memory controllers and I/O ports, (e.g., up to 16 memory channels). In some examples, the memory controllers 1520 may implement a memory interleave (e.g., one memory address is mapped to the memory set 1530, the next memory address is mapped to the memory set 1532, and the third address is mapped to the memory set 1530, etc.). The interleaving may be managed within the memory controllers 1520, or from CPU sockets (e.g., of the compute sled 900) across network links to the memory sets 1530, 1532, and may improve the latency associated with performing memory access operations as compared to accessing contiguous memory addresses from the same memory device.

Further, in some examples, the memory sled 1500 may be connected to one or more other sleds 500 (e.g., in the same rack 340 or an adjacent rack 340) through a waveguide, using the waveguide connector 1580. In the illustrative example, the waveguides are 74 millimeter waveguides that provide 16 Rx (i.e., receive) lanes and 16 Tx (i.e., transmit) lanes. Different ones of the lanes, in the illustrative example, are either 16 GHz or 32 GHz. In other examples, the frequencies may be different. Using a waveguide may provide high throughput access to the memory pool (e.g., the memory sets 1530, 1532) to another sled (e.g., a sled 500 in the same rack 340 or an adjacent rack 340 as the memory sled 1500) without adding to the load on the optical data connector 934.

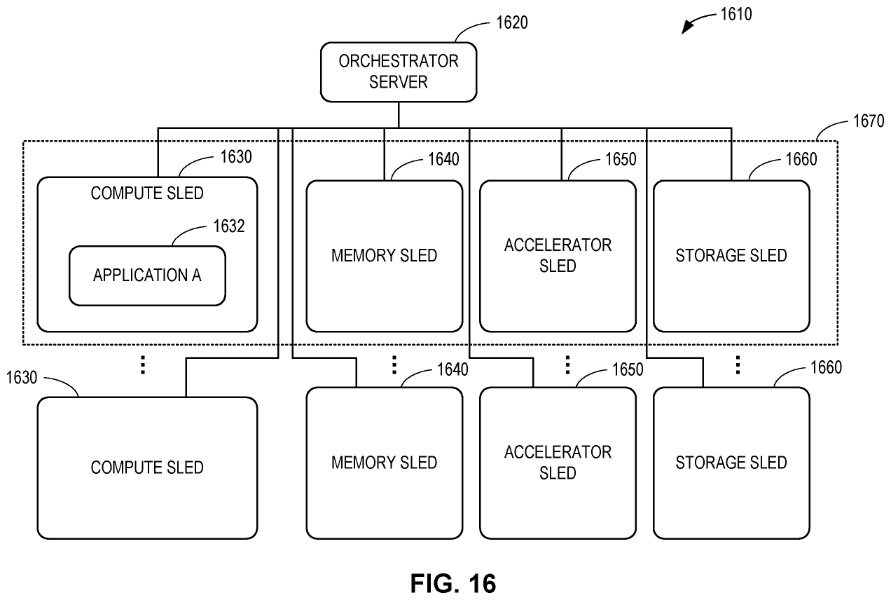

Referring now to FIG. 16, a system for executing one or more workloads (e.g., applications) may be implemented in accordance with the data center 200. In the illustrative example, the system 1610 includes an orchestrator server 1620, which may be implemented as a managed node including a compute device (e.g., processor circuitry 920 on a compute sled 900) executing management software (e.g., a cloud operating environment, such as OpenStack) that is communicatively coupled to multiple sleds 500 including a large number of compute sleds 1630 (e.g., similar to the compute sled 900), memory sleds 1640 (e.g., similar to the memory sled 1500), accelerator sleds 1650 (e.g., similar to the memory sled 1000), and storage sleds 1660 (e.g., similar to the storage sled 1300). One or more of the sleds 1630, 1640, 1650, 1660 may be grouped into a managed node 1670, such as by the orchestrator server 1620, to collectively perform a workload (e.g., an application 1632 executed in a virtual machine or in a container). The managed node 1670 may be implemented as an assembly of physical resources 720, such as processor circuitry 920, memory resources 820, accelerator circuits 1120, or data storage 1350, from the same or different sleds 500. Further, the managed node may be established, defined, or “spun up” by the orchestrator server 1620 at the time a workload is to be assigned to the managed node or at any other time, and may exist regardless of whether any workloads are presently assigned to the managed node. In the illustrative example, the orchestrator server 1620 may selectively allocate and/or deallocate physical resources 720 from the sleds 500 and/or add or remove one or more sleds 500 from the managed node 1670 as a function of quality of service (QOS) targets (e.g., a target throughput, a target latency, a target number of instructions per second, etc.) associated with a service level agreement for the workload (e.g., the application 1632). In doing so, the orchestrator server 1620 may receive telemetry data indicative of performance conditions (e.g., throughput, latency, instructions per second, etc.) in different ones of the sleds 500 of the managed node 1670 and compare the telemetry data to the quality of service targets to determine whether the quality of service targets are being satisfied. The orchestrator server 1620 may additionally determine whether one or more physical resources may be deallocated from the managed node 1670 while still satisfying the QoS targets, thereby freeing up those physical resources for use in another managed node (e.g., to execute a different workload). Alternatively, if the QoS targets are not presently satisfied, the orchestrator server 1620 may determine to dynamically allocate additional physical resources to assist in the execution of the workload (e.g., the application 1632) while the workload is executing. Similarly, the orchestrator server 1620 may determine to dynamically deallocate physical resources from a managed node if the orchestrator server 1620 determines that deallocating the physical resource would result in QoS targets still being met.

Additionally, in some examples, the orchestrator server 1620 may identify trends in the resource utilization of the workload (e.g., the application 1632), such as by identifying phases of execution (e.g., time periods in which different operations, having different resource utilizations characteristics, are performed) of the workload (e.g., the application 1632) and pre-emptively identifying available resources in the data center 200 and allocating them to the managed node 1670 (e.g., within a predefined time period of the associated phase beginning). In some examples, the orchestrator server 1620 may model performance based on various latencies and a distribution scheme to place workloads among compute sleds and other resources (e.g., accelerator sleds, memory sleds, storage sleds) in the data center 200. For example, the orchestrator server 1620 may utilize a model that accounts for the performance of resources on the sleds 500 (e.g., FPGA performance, memory access latency, etc.) and the performance (e.g., congestion, latency, bandwidth) of the path through the network to the resource (e.g., FPGA). As such, the orchestrator server 1620 may determine which resource(s) should be used with which workloads based on the total latency associated with different potential resource(s) available in the data center 200 (e.g., the latency associated with the performance of the resource itself in addition to the latency associated with the path through the network between the compute sled executing the workload and the sled 500 on which the resource is located).

In some examples, the orchestrator server 1620 may generate a map of heat generation in the data center 200 using telemetry data (e.g., temperatures, fan speeds, etc.) reported from the sleds 500 and allocate resources to managed nodes as a function of the map of heat generation and predicted heat generation associated with different workloads, to maintain a target temperature and heat distribution in the data center 200. Additionally or alternatively, in some examples, the orchestrator server 1620 may organize received telemetry data into a hierarchical model that is indicative of a relationship between the managed nodes (e.g., a spatial relationship such as the physical locations of the resources of the managed nodes within the data center 200 and/or a functional relationship, such as groupings of the managed nodes by the customers the managed nodes provide services for, the types of functions typically performed by the managed nodes, managed nodes that typically share or exchange workloads among each other, etc.). Based on differences in the physical locations and resources in the managed nodes, a given workload may exhibit different resource utilizations (e.g., cause a different internal temperature, use a different percentage of processor or memory capacity) across the resources of different managed nodes. The orchestrator server 1620 may determine the differences based on the telemetry data stored in the hierarchical model and factor the differences into a prediction of future resource utilization of a workload if the workload is reassigned from one managed node to another managed node, to accurately balance resource utilization in the data center 200. In some examples, the orchestrator server 1620 may identify patterns in resource utilization phases of the workloads and use the patterns to predict future resource utilization of the workloads.

To reduce the computational load on the orchestrator server 1620 and the data transfer load on the network, in some examples, the orchestrator server 1620 may send self-test information to the sleds 500 to enable a given sled 500 to locally (e.g., on the sled 500) determine whether telemetry data generated by the sled 500 satisfies one or more conditions (e.g., an available capacity that satisfies a predefined threshold, a temperature that satisfies a predefined threshold, etc.). The given sled 500 may then report back a simplified result (e.g., yes or no) to the orchestrator server 1620, which the orchestrator server 1620 may utilize in determining the allocation of resources to managed nodes.

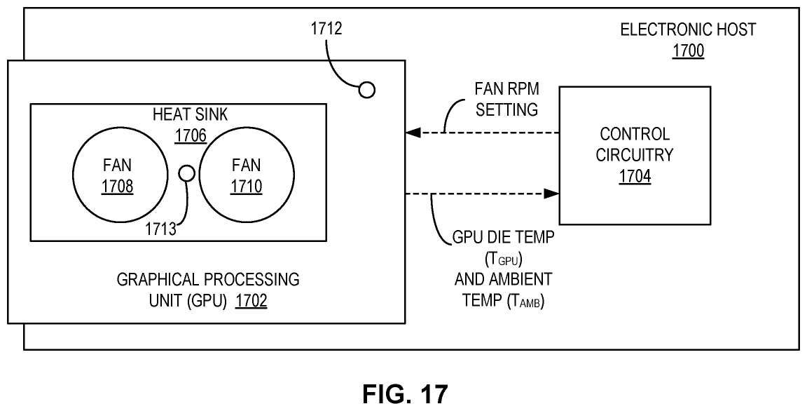

FIG. 17 is an illustration of an example implementation of an electronic host 1700, including a GPU 1702 and control circuitry 1704 that is electronically coupled to the GPU 1702. A first temperature sensor 1712 is integrated into the GPU 1702, and a second temperature sensor 1713 is coupled to a heatsink 1706. In some examples, the first temperature sensor 1712 may be integrated into and/or part of packaging of an integrated circuit (e.g., the GPU 1702). In some examples, the second temperature sensor 1713 is coupled to a fan intake of a chassis that may at least partially enclose an electronic host 1700.

The control circuitry 1704 may provide control instructions to a first fan 1708 and/or a second fan 1710 to cause the GPU 1702 to maintain a thermal setpoint temperature (e.g., target GPU operation at a selected temperature). For example, the thermal setpoint temperature may be maintained based on a set temperature fan control method in which the speed of the fan is varied to cause the GPU 1702 to operate at the selected thermal setpoint.

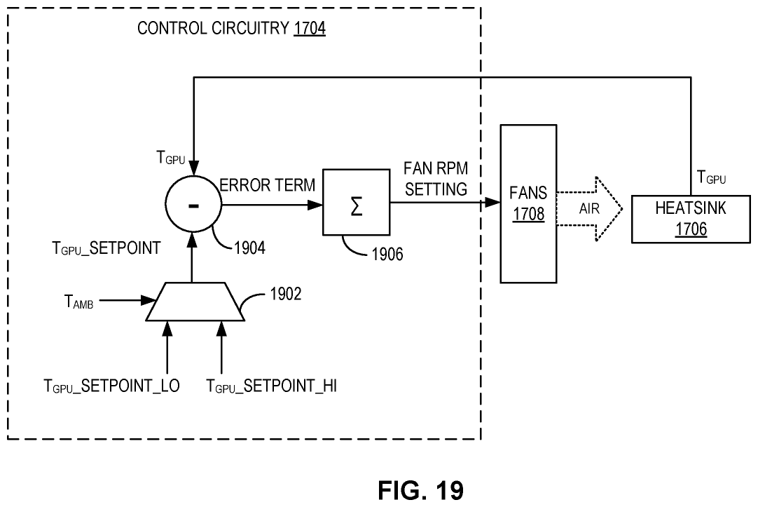

To facilitate generation of the control instructions, The GPU 1702 may provide, to the control circuitry 1704, (1) a die temperature of the GPU 1702 (e.g., from the second sensor 1712); and (2) an ambient temperature 1718 of the GPU. The control circuitry 1704 may determine a thermal setpoint for the GPU 1702. In some examples, the GPU 1702 may execute a control loop to select a thermal setpoint for the GPU 1702 and adjust a rotational speed of a first fan 1708 and/or a second fan 1710 based on the ambient temperature. An example control loop to adjust a rotational speed of the first fan 1708 (e.g., and/or any other fans) will be described in association with FIG. 19.

The ambient temperature sensor (e.g., the second temperature sensor) 1713 is associated with an ambient region of the heatsink. The ambient temperature sensor 1713 can provide a temperature reading to the control circuitry 1704 (e.g., via the electronic host 1700) to assess thermal conditions that affect a temperature of the GPU 1702. In some examples, the ambient temperature sensor 1713 is not integrated with the heatsink 1706, but is instead integrated on the electronic host 1700. When the ambient temperature sensor 1713 is integrated on the electronic host 1700, the control circuitry 1704 may receive the temperature directly from the ambient temperature sensor 1713 instead of the GPU 1702.

In the illustrated example of FIG. 17, the control circuitry 1704 is integrated with the electronic host 1700 (e.g., off-chip of the GPU 1702). In some examples, the control circuitry 1704 is integrated with the GPU 1702 such that control of the first fan 1708 and the second fan 1710 is at least partially implemented on the GPU 1702 (e.g., in examples with partial execution of control loop on the GPU 1702, host processor(s)/controller(s) can perform the remainder). In any of these approaches, dedicated logic circuitry (e.g., field programmable gate array (FPGA), application specific integrated circuit (ASIC)) can be used, partially or wholly with respect to the implementation of the control circuitry 1704, instead of the execution of non-transitory computer readable instructions. In some examples, additionally or alternatively to the GPU 1702, the electronic host 1700 includes programmable circuitry, a second graphics processor, an artificial intelligence accelerator, and/or a network processor.

In some examples, the control circuitry 1704 may select one of two thermal setpoints. The thermal setpoint for the GPU 1702 may include a high thermal setpoint (e.g., “HI”) and a low thermal setpoint (e.g., “LO”). In other examples, the control circuitry may have three or more thermal setpoints (e.g., a “middle” setpoint reference can be established between the HI and LO setpoint references that is selected for medium ambient temperatures that are neither high nor low). In some examples, the control circuitry 1704 may, based on control of a rotational speed of a fan, cause programmable circuitry to satisfy a thermal threshold.

Although the control circuitry 1704 is described as controlling the GPU 1702, the control circuitry may be associated with fan control and/or thermal setpoint selection for other types of processor circuitry (e.g., that includes functionality other than graphics processing). Examples include accelerators for artificial intelligence (e.g., machine learning engines, inference engines, neural network processors), “X” processors (XPUs), network processors, digital signal processors (DSPs), high performance memory or storage modules, etc. Thus, the control circuitry 1704 may applied to any of a number of different types of circuitry (e.g., storage circuitry, memory circuitry, networking adaptor circuitry, etc.).

Some examples may include more than one processing unit (e.g., with respective chip/die temperatures) that is controlled by the control circuitry 1704. In such an example, one or more of the chip/die temperatures may be used for calculation of an error term by the control circuitry 1704. In such an example, if different fans are used to cool different ones of the more than one processing units, the control circuitry 1704 may implement multiple, different control loops (e.g., one for each processing unit and its associated fan). In other examples, if a single fan is used to cool more than one processing unit, the control circuitry 1704 may perform one or more of the following operations to generate a temperature for use in the various control methods described herein: (1) determine an average of the multiple chip temperatures; (2) select the highest temperature of the multiple chip temperatures; (3) provide the multiple chip temperatures to a machine learning model that outputs the chip temperature; (4) use any other method to combine the multiple chip temperatures into a single temperature for thermal setpoint. In various embodiments, multiple high performance chips can comprise a single chip package that is coupled to a heatsink. Then, the control circuitry 1704 may receive temperature readings from more than one chip within the package.

In some examples, one or more of the heat sink 1706, the fan 1710, the first temperature sensor 1712, the second temperature sensor 1713, and/or the control circuitry 1704 may be retrofit to an electronic host and/or a pre-existing system (e.g., a pre-existing operational system). For example, a system may be configured with a first temperature sensor that is integrated into processor circuitry of the system, but the system may lack a second temperature sensor, means for generating airflow (e.g., a fan), and/or control circuitry (e.g., to select and maintain a thermal threshold). According to examples disclosed herein, such a system may be retrofit with a second temperature sensor (e.g., the second temperature sensor 1713), a fan (e.g., the fan 1708), and/or control circuitry (e.g., the control circuitry 1704), to provide and/or add capabilities to the electronic host for set target temperature fan control using ambient temperature.

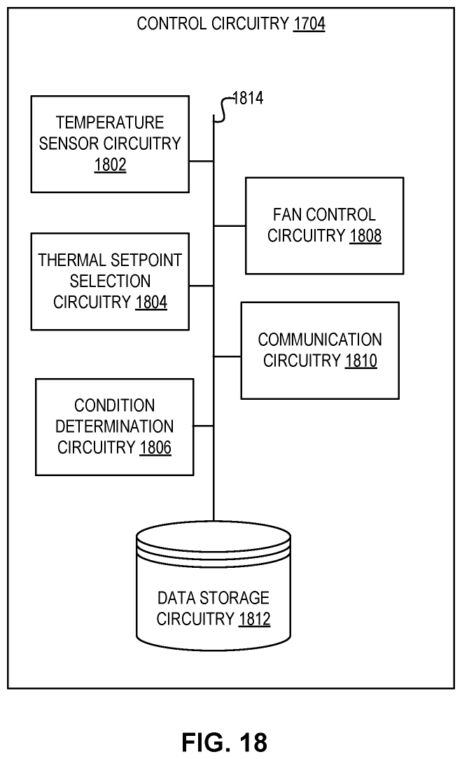

FIG. 18 is a block diagram of one example of the control circuitry 1704 for fan control based on ambient temperature. The control circuitry 1704 of FIG. 18 may be instantiated (e.g., creating an instance of, bring into being for any length of time, materialize, implement, etc.) by processor circuitry such as a central processing unit executing instructions. Additionally or alternatively, the control circuitry 1704 of FIG. 18 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 18 may, thus, be instantiated at the same or different times. Some or all of the circuitry may be instantiated, for example, in one or more threads executing concurrently on hardware and/or in series on hardware. Moreover, in some examples, some or all of the circuitry of FIG. 18 may be implemented by microprocessor circuitry executing instructions to implement one or more virtual machines and/or containers. In some examples, some or all of the circuitry of FIG. 18 may be implemented by a GPU, an IPU, etc.

The example control circuitry 1704 includes example temperature sensor circuitry 1802, example thermal setpoint selection circuitry 1804, example condition determination circuitry 1806, example fan control circuitry 1808, example communication circuitry 1810, and example data storage circuitry 1812.

The example temperature sensor circuitry 1802 may include one or more temperature sensors to determine a temperature of the GPU 1702. The temperature sensor circuitry 1802 responds to changes in temperature (e.g., a change in temperature of the GPU 1702) by generating a signal. The signal may be an analog signal or a digital signal, depending on sensor type. The temperature sensor circuitry 1802 may include any number of analog, digital, and/or thermocouple sensors. For example, the first temperature sensor 1712 of FIG. 17 is integrated into the GPU 1702, while the second temperature sensor 1713 is located at the heatsink 1706 that is thermally coupled to the GPU. The temperature sensor circuitry 1802 may determine a first temperature (e.g., a GPU die temperature, an infrastructure processing unit temperature, a neural network accelerator temperature, etc.,) at a first location (e.g., the GPU die, the IPU die, the neural network accelerator die) that is associated with second programmable circuitry (e.g., the GPU, the IPU, the neural network accelerator). The temperature sensor circuitry 1802 may then determine a second temperature (e.g., an ambient temperature, a room temperature, etc.) at a second location (e.g., ambient to the GPU, ambient to the IPU, etc.) that is different than the first location.

In some examples, the temperature sensor circuitry 1802 may determine one or more additional temperatures at various locations that are associated with a processing unit (e.g., a GPU, a processor, etc.). For example, the thermal setpoint selection circuitry 1804 may determine a temperature at the processing unit and a temperature in a room in which the processing unit is located (e.g., a server room, an office space, a bedroom, etc.). The temperature sensor circuitry 1802 may determine the temperature of the processing unit with a thermistor and determine the temperature at multiple locations (e.g., zones, areas, etc.) throughout the room. The temperature readings can be provided to the thermal setpoint selection circuitry 1804, which can determine a thermal setpoint for the processing unit.

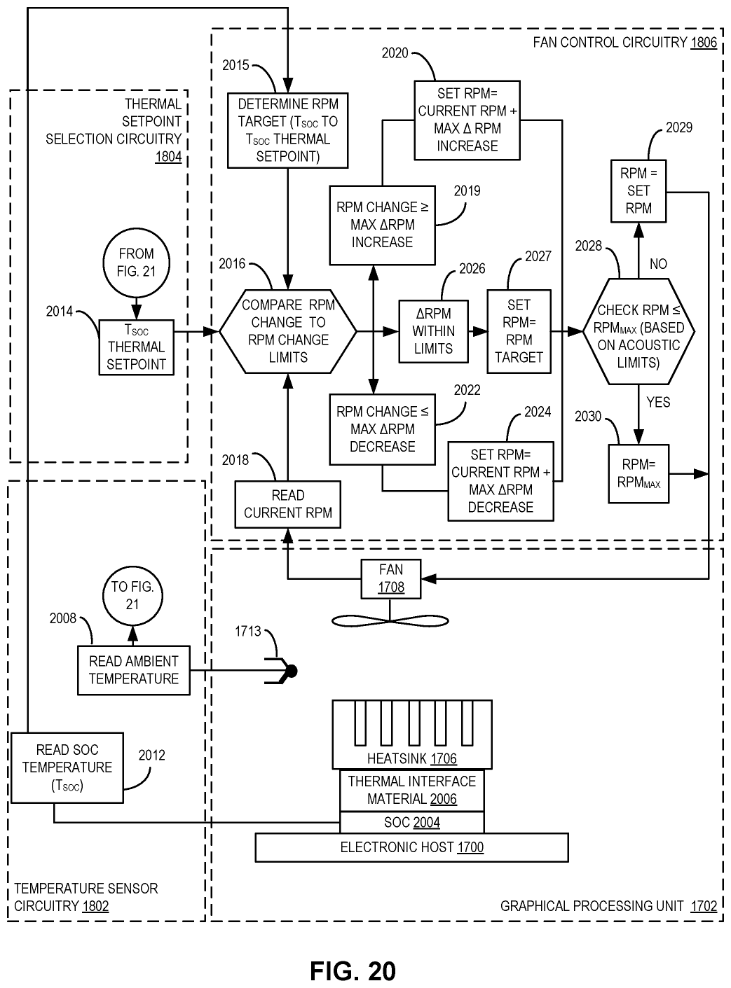

In some examples, the temperature sensor circuitry 1802 circuitry is instantiated by processor circuitry executing temperature sensor instructions and/or configured to perform operations such as those represented by the flowcharts of FIGS. 20-23.

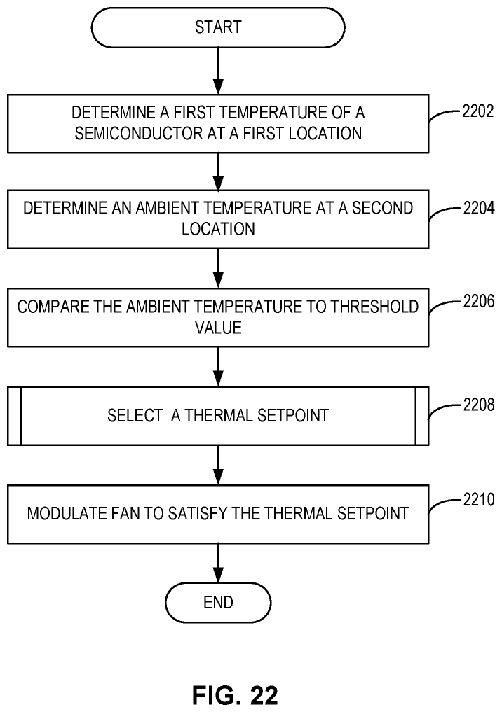

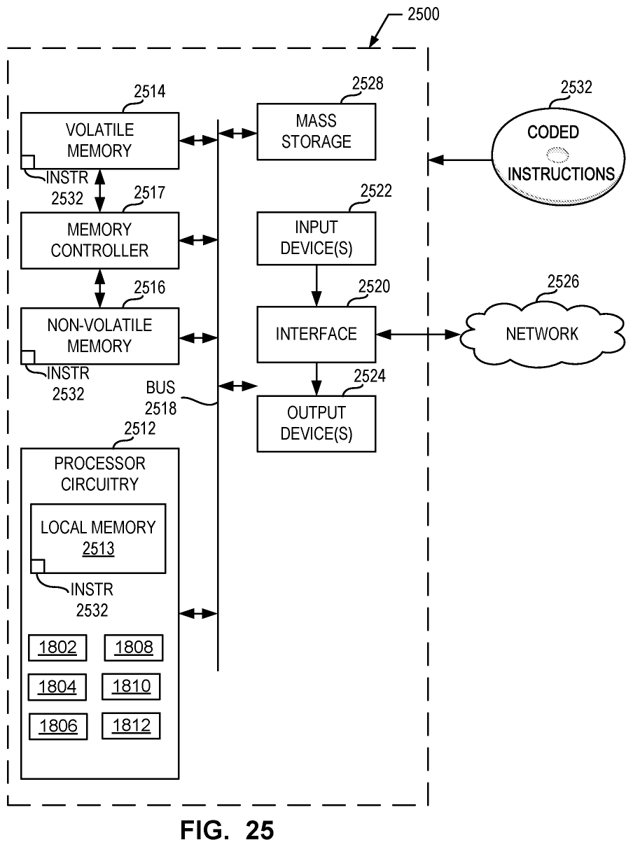

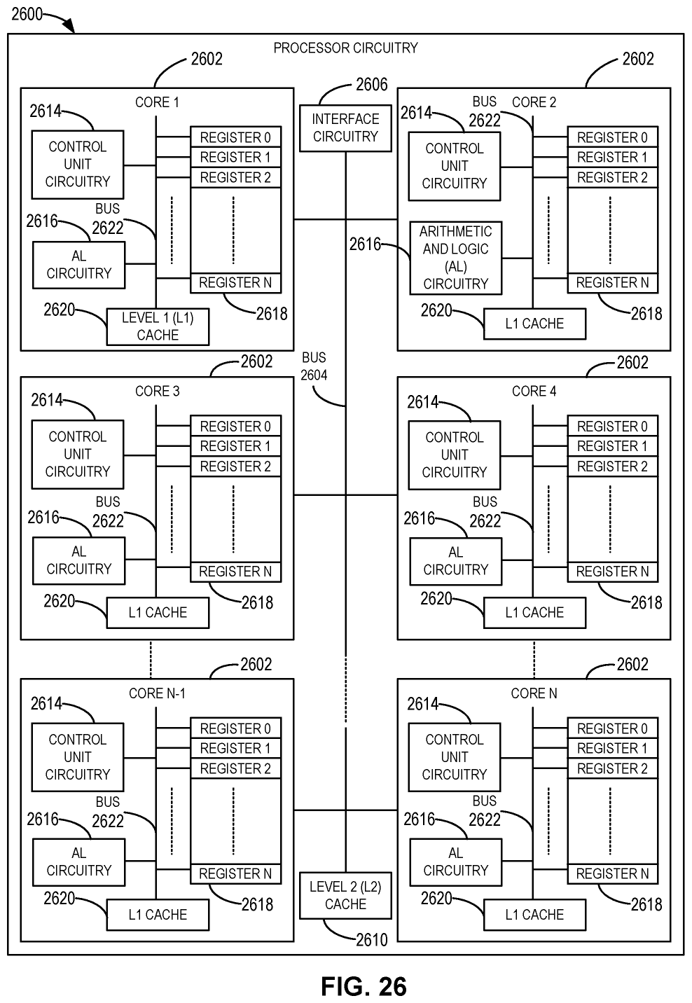

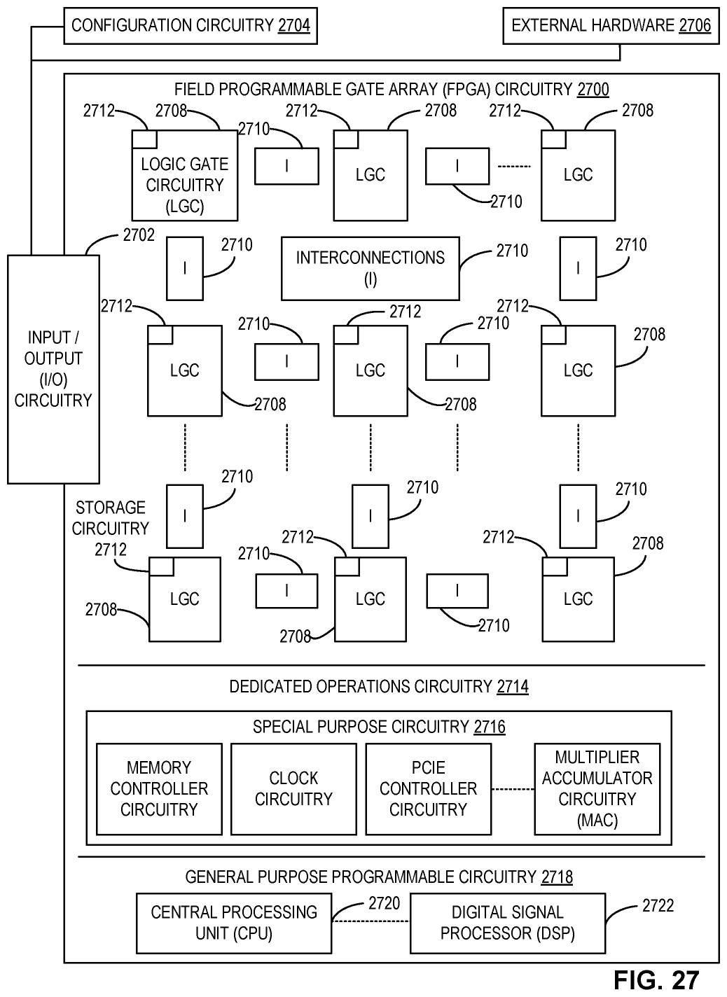

In some examples, the control circuitry 1704 includes means for a first temperature sensor to output a first signal indicative of a temperature of an integrated circuit and/or a second temperature sensor to output a second signal indicative of a temperature ambient to the integrated circuit. In some examples, the control circuitry 1704 includes means to determine, based on a first signal output by a first sensor, a first temperature at a first location that is associated with programmable circuitry such as a GPU, an IPU, a machine learning accelerator, etc., and determine, based on a second signal output by a second sensor, a second temperature at a second location that is different than the first location. For example, the means for determining temperatures may be implemented by temperature sensor circuitry 1802. In some examples, the temperature sensor circuitry 1802 may be instantiated by processor circuitry such as the example processor circuitry 2512 of FIG. 25. For instance, the temperature sensor circuitry 1802 may be instantiated by the example microprocessor 2600 of FIG. 26 executing machine executable instructions such as those implemented by at least blocks 2202 and block 2204 of FIG. 22. In some examples, temperature sensor circuitry 1802 may be instantiated by hardware logic circuitry, which may be implemented by an ASIC, XPU, or the FPGA circuitry 2700 of FIG. 27 structured to perform operations corresponding to the machine readable instructions. Additionally or alternatively, the temperature sensor circuitry 1802 may be instantiated by any other combination of hardware, software, and/or firmware. For example, the temperature sensor circuitry 1802 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The control circuitry 1704 includes the thermal setpoint selection circuitry 1804. The thermal setpoint selection circuitry 1804 determines one or more thermal setpoint temperatures for a processing unit (e.g., a GPU, an IPU, a neural network accelerator, etc.). in some examples, the thermal setpoint selection circuitry 1804 selects a thermal setpoint based on a comparison of an ambient temperature to an ambient thermal threshold. A specific setpoint temperatures range may be a characteristic of the relevant processing unit. For example, a processor may be designed for a maximum thermal operation temperature (e.g., TJunction, temperature above which transistor performs unexpectedly) after which the CPU will throttle and slow down so as to prevent the chip from going over that maximum temperature. A high thermal setpoint temperature value may be based on this maximum temperature. A low thermal setpoint may be determined based on processing unit characteristics (e.g., most efficient operating temperature, power consumption, etc.), an amount of noise generated by a fan that maintains the GPU temperature, a user tolerance to the noise, a user preference, etc.).

The thermal setpoint selection circuitry 1804 may also determine a threshold value (e.g., a threshold ambient temperature value) for use in determining which thermal setpoint to assign to a processor unit (e.g., a low or a high thermal setpoint). For example, the threshold ambient temperature value (e.g., 27 degrees Celsius) may be associated with a temperature at which a user is more accepting of increased fan noise, as the environment feels warm to the user. When the user is in a relatively cold environment (e.g., 11 degrees Celsius), the user may find fan noise unacceptable.

The example thermal setpoint selection circuitry 1804 may set a first thermal setpoint (e.g., a low thermal setpoint) for programmable circuitry (e.g., a GPU, an IPU, a neural network accelerator, etc.) in response to a temperature failing to satisfy a threshold value. Failing to satisfy a threshold temperature value could involve the ambient temperature (e.g., measured at a chassis intake, measured in a room, measured at a semiconductor) being lower than the threshold ambient temperature value. Furthermore, failing to satisfy the threshold temperature value may involve the ambient temperature (e.g., measured at chassis intake, measured in a room, measured at a semiconductor, etc.) failing to drop below the threshold temperature value. Furthermore, failing to satisfy a threshold ambient temperature value may involve failing to maintain the threshold ambient temperature value for a duration of time, failing to exceed a threshold ambient temperature value for a duration of time, failing to drop below a threshold temperature value for a duration of time, etc. Satisfying the threshold temperature value could involve the ambient temperature (e.g., measured at a chassis intake, measured in a room, measured at a semiconductor) being greater than and/or equal to than the threshold temperature value.

The thermal setpoint selection circuitry 1804 may set a second thermal setpoint for the second programmable circuitry in response to the second temperature satisfying the threshold value, wherein the second thermal setpoint is higher than the first thermal setpoint. Satisfying the threshold temperature value may involve the ambient temperature (e.g., measured at chassis intake, measured in a room, measured at a semiconductor, etc.) exceeding the threshold temperature value.

In some examples, the thermal setpoint selection circuitry 1804 is instantiated by processor circuitry executing thermal setpoint selection instructions and/or configured to perform operations such as those represented by the flowcharts of FIGS. 20-23.

In some examples, the control circuitry 1704 includes means for setting a first thermal setpoint for the second programmable circuitry in response to the second temperature failing to satisfy a threshold value, and setting a second thermal setpoint for the second programmable circuitry in response to the second temperature satisfying the threshold value, wherein the second thermal setpoint is higher than the first thermal setpoint. In some examples, the control circuitry 1704 includes means for setting a first thermal setpoint in response to the ambient temperature exceeding a threshold value plus a gap band temperature value; setting a second thermal setpoint in response to the ambient temperature being less than the threshold value minus the gap band temperature value.

For example, the means for setting may be implemented by thermal setpoint selection circuitry 1804. In some examples, the thermal setpoint selection circuitry 1804 may be instantiated by processor circuitry such as the example processor circuitry 2512 of FIG. 25. For instance, the thermal setpoint selection circuitry 1804 may be instantiated by the example microprocessor 2600 of FIG. 26 executing machine executable instructions such as those implemented by at least blocks 2208 of FIG. 7. In some examples, the thermal setpoint selection circuitry 1804 may be instantiated by hardware logic circuitry, which may be implemented by an ASIC, XPU, or the FPGA circuitry 2700 of FIG. 27 structured to perform operations corresponding to the machine readable instructions. Additionally or alternatively, the thermal setpoint selection circuitry 1804 may be instantiated by any other combination of hardware, software, and/or firmware. For example, the thermal setpoint selection circuitry 1804 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The control circuitry 1704 includes the condition determination circuitry 1806. The condition determination circuitry 1806 provides interoperability with additional sensors that may determine conditions and/or around a processing unit (e.g., a GPU). For example, the condition determination circuitry 1806 may be coupled to a microphone to measure noise in a room (e.g., a server room) and provide the noise measurement to the thermal setpoint selection circuitry 1804 for adjustment of a thermal setpoint and/or to the fan control circuitry 1808 for adjustment of a fan rotations per minute (RPM) associated with the fan.

Furthermore, the condition determination circuitry 1806 provides the ability to expand features of the control circuitry 1704 (e.g., connect additional sensors, add new circuitry to determine characteristics associated with ambient temperatures, measure humidity, etc.). In some examples, condition determination circuitry 1806 determines the condition a workload and/or a noise level associated with a fan cooling an SoC executing the workload. For example, if a GPU workload increases and the thermal setpoint selection circuitry 1804 has a low threshold selected, more noise may be (e.g., temporarily) allowed to accommodate the increased workload.

In some examples, the control circuitry 1704 circuitry is instantiated by processor circuitry executing condition determination circuitry 1806 instructions and/or configured to perform operations such as those represented by the flowcharts of FIGS. 20-23.

In some examples, the control circuitry 1704 includes means for determining a condition of a device. For example, the means for determining may be implemented by condition determination circuitry 1806. In some examples, the condition determination circuitry 1806 may be instantiated by processor circuitry such as the example processor circuitry 2512 of FIG. 25. For instance, the condition determination circuitry 1806 may be instantiated by the example microprocessor 2600 of FIG. 26 executing machine executable instructions such as those implemented by at least blocks 2204 of block 22. In some examples, condition determination circuitry 1806 may be instantiated by hardware logic circuitry, which may be implemented by an ASIC, XPU, or the FPGA circuitry 2700 of FIG. 27 structured to perform operations corresponding to the machine readable instructions. Additionally or alternatively, the condition determination circuitry 1806 may be instantiated by any other combination of hardware, software, and/or firmware. For example, the condition determination circuitry 1806 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The control circuitry 1704 includes the fan control circuitry 1808. The fan control circuitry 1808 may change a rotational speed of a fan blade (e.g., modulated, RPM change, etc.) based on one or more of ambient sound at the second location or a workload associated with programmable circuitry to satisfy: (1) a first thermal setpoint (e.g., a low thermal setpoint); or (2) a second (e.g., high) thermal setpoint. To change the fan speed of a fan associated with the programmable circuitry (e.g., the GPU 1702 of FIG. 7) the fan control circuitry 1808 may determine a current rotational speed of the fan. Then, the fan control circuitry 1808 may determine a target rotational speed for the fan. For example, the target rotational speed may be 2000 RPM greater than the current rotational speed. The fan control circuitry 1808 may then determine that a difference between the current rotational speed and the target rotational speed satisfies a threshold RPM change value. The threshold RPM change value is a threshold to ensure that the fan is not accelerated/decelerated too rapidly, causing an unacceptable level of noise. In response to the satisfying the threshold RPM change value, the fan control circuitry 1808 may set the fan to a speed that is approximately the current rotational speed plus the threshold RPM change value.

In some examples, the fan control circuitry 1808 may increase a speed of the fan more rapidly than the fan control circuitry 1808 causes the fan to decelerate. This is because, while an increased noise level may be unavoidable when exceeding a thermal threshold (e.g., chip will turn off if too hot), there is no such constraint on deceleration.

In general, rapid fluctuations in fan RPM can cause unnecessary noise. Thus some examples include a guard-band temperature range that prevents relatively large and/or noticeable fluctuations in the acoustics when the ambient temperature fluctuates within the guard-band temperature range. For example, a threshold temperature value may be defined as 35 degrees Celsius. Therefore, the thermal setpoint selection circuitry 1804 would select a low thermal setpoint for temperatures below 35 degrees Celsius, and the thermal setpoint selection circuitry 1804 would select a high thermal setpoint when the temperature is above 35 degrees Celsius. However, at values that are near the threshold temperature value, a small change in temperature could cause an unnecessary noise (e.g., fan spinning up, slowing down, spinning up again, etc.). In general, sharp changes in fan speed are to be minimized when possible because the change may be audible to the user. Thus, the fan control circuitry 1808 may maintain a fan rotational speed when the temperature is within the guard-band (e.g., gap band) temperature range. Furthermore, if there is a relatively large temperature change, the fan control circuitry 1808 can avoid a sharp change in acoustics that would become audible to a user by gradually changing the RPM of the fan.

In some examples, there may be two or more guard-band temperature ranges. For example, a first guard-band temperature range may be directed to a temperature of integrated circuitry, and a second guard-band temperature range may be directed to a temperature of one or more hardware elements (e.g., servers, compute hardware, etc.) that are associated with the integrated circuitry. That is, the first guard-band temperature range may be based on a capability of a control system, while a second guard-band temperature range (different from the first guard-band temperature range) may be based on a capability of equipment (e.g., a compute system, a server farm, etc.) associated with the control system. In such an example, the first guard-band temperature range may be associated with control circuitry (e.g., programmable circuitry, a circuit board, an electronic host) that controls one or more fans. In turn, the example second guard-band temperature range may be associated with any other type of hardware (e.g., hardware of a server system, server room hardware, etc.) that further controls the one or more fans. In any of the examples described herein, a guard-band temperature range may be associated with an uncertainty value. For example, circuitry that is to manage a guard-band temperature range may only be capable of managing the temperature range within a threshold level of uncertainty (e.g., +−2%, etc.). Therefore, relatively small deviations from a threshold temperature range may be accounted for by selecting an appropriate threshold level of uncertainty. For example, the threshold level of uncertainty may be selected corresponding to capabilities of the control circuitry and/or other hardware of a control system.

In some examples, the control circuitry 1704 includes means for controlling a fan based on one or more of ambient sound at the second location or a workload associated with the second programmable circuitry. For example, the means for controlling may be implemented by fan control circuitry 1808. In some examples, the fan control circuitry 1808 may be instantiated by processor circuitry such as the example processor circuitry 2512 of FIG. 25. For instance, the fan control circuitry 1808 may be instantiated by the example microprocessor 2600 of FIG. 26 executing machine executable instructions such as those implemented by at least blocks 2210 of FIG. 22. In some examples, fan control circuitry 1808 may be instantiated by hardware logic circuitry, which may be implemented by an ASIC, XPU, or the FPGA circuitry 2700 of FIG. 27 structured to perform operations corresponding to the machine readable instructions. Additionally or alternatively, the fan control circuitry 1808 may be instantiated by any other combination of hardware, software, and/or firmware. For example, the fan control circuitry 1808 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

The control circuitry 1704 includes the communication circuitry 1810. The communication circuitry 1810 facilitates communication between the temperature sensor circuitry 1802, the thermal setpoint selection circuitry 1804, the condition determination circuitry 1806, the fan control circuitry 1808, the data storage circuitry 1812, and/or any other circuitry for set point temperature fan control based on ambient temperature. For example, the communication circuitry 1810 may carry a signal from the control circuitry 1704 to a secondary processor circuitry. The communication circuitry 1810 may electronically couple the temperature sensor circuitry 1802, the thermal setpoint selection circuitry 1804, the condition determination circuitry 1806, the fan control circuitry 1808, the data storage circuitry 1812, and/or any other circuitry for set point temperature fan control based on ambient temperature by facilitating communication over the bus 1814. The communication circuitry 1810 may further connect to a network (e.g., such as the Internet) for communication.

The data storage circuitry 1812 may store any information generated by the temperature sensor circuitry 1802, the thermal setpoint selection circuitry 1804, the condition determination circuitry 1806, the fan control circuitry 1808, the data storage circuitry 1812, and/or any other circuitry for set point temperature fan control based on ambient temperature. In some examples, the communication circuitry 1810 is instantiated by processor circuitry executing communication instructions and/or configured to perform operations such as those represented by the flowcharts of FIGS. 20-23.

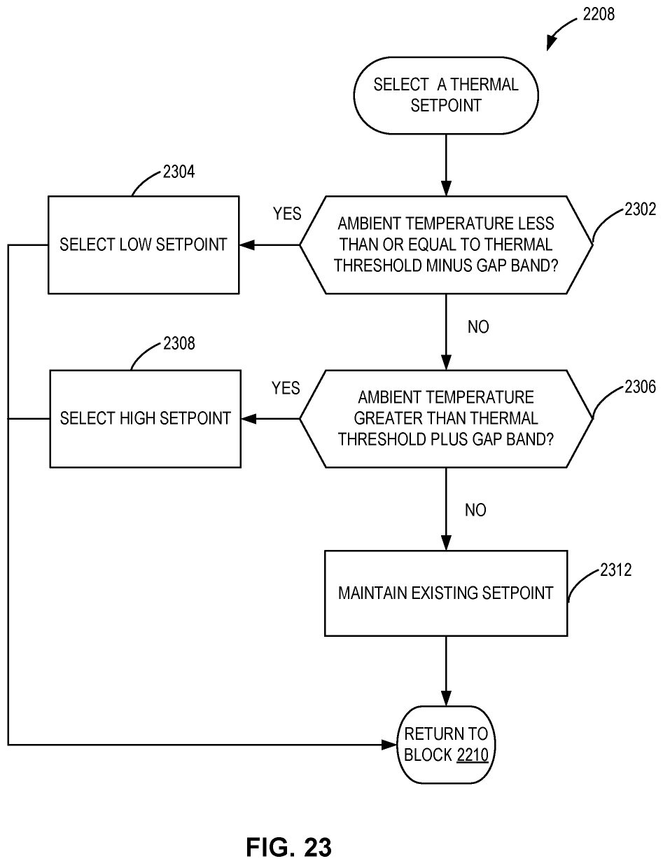

In some examples, the control circuitry 1704 includes means for communicating between portions of the control circuitry. For example, the means for communicating may be implemented by communication circuitry 1810. In some examples, the communication circuitry 1810 may be instantiated by processor circuitry such as the example processor circuitry 2512 of FIG. 25. For instance, communication circuitry 1810 may be instantiated by the example microprocessor 2600 of FIG. 26 executing machine executable instructions such as those implemented by at least FIGS. 22 and 23. In some examples, communication circuitry 1810 may be instantiated by hardware logic circuitry, which may be implemented by an ASIC, XPU, or the FPGA circuitry 2700 of FIG. 27 structured to perform operations corresponding to the machine readable instructions. Additionally or alternatively, the communication circuitry 1810 may be instantiated by any other combination of hardware, software, and/or firmware. For example, the communication circuitry 1810 may be implemented by at least one or more hardware circuits (e.g., processor circuitry, discrete and/or integrated analog and/or digital circuitry, an FPGA, an ASIC, an XPU, a comparator, an operational-amplifier (op-amp), a logic circuit, etc.) structured to execute some or all of the machine readable instructions and/or to perform some or all of the operations corresponding to the machine readable instructions without executing software or firmware, but other structures are likewise appropriate.

One example apparatus in accordance with FIG. 18 may include: means for determining a condition (e.g., the condition determination circuitry 1806) to: determine, based on a first signal output by a first sensor, a first temperature at a first location that is associated with programmable circuitry; determine, based on a second signal output by a second sensor, a second temperature at a second location that is different than the first location; and means for selecting a thermal setpoint (e.g., the thermal setpoint selection circuitry 1804) to: select a first thermal setpoint for the programmable circuitry in response to the second temperature failing to satisfy a threshold value; and select a second thermal setpoint for the programmable circuitry in response to the second temperature satisfying the threshold value, wherein the second thermal setpoint is higher than the first thermal setpoint.

While an example manner of implementing the control circuitry 1704 of FIG. 17 is illustrated in FIG. 18, one or more of the elements, processes, and/or devices illustrated in FIG. 18 may be combined, divided, re-arranged, omitted, eliminated, and/or implemented in any other way. Further, the example temperature sensor circuitry 1802, the example thermal setpoint selection circuitry 1804, the example condition determination circuitry 1806, the example fan control circuitry 1808, the example communication circuitry 1810, and/or the example data storage circuitry 1812 may be implemented by hardware alone or by hardware in combination with software and/or firmware. Thus, for example, any the example temperature sensor circuitry 1802, the example thermal setpoint selection circuitry 1804, the example condition determination circuitry 1806, the example fan control circuitry 1808, the example communication circuitry 1810, and/or the example data storage circuitry 1812, and/or, more generally, the example control circuitry 1704, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example control circuitry 1704 of FIG. 18 may include one or more elements, processes, and/or devices in addition to, or instead of, those illustrated in FIG. 18, and/or may include more than one of any or all of the illustrated elements, processes and devices.

FIG. 19 is a block diagram of a control loop that may be executed by the control circuitry 1704 of FIG. 17. FIG. 19 includes the control circuitry 1704, the fan 1708, and a heatsink 1706. The control circuitry 1704 includes a multiplexer 1902, difference circuitry 1904, and summation circuitry 1906.

The control circuitry 1704 implements a dynamic control loop for GPU fan control based on ambient temperature. In the dynamic control loop, the multiplexer 1902 first selects one of two possible thermal setpoints (e.g., reference values): a high thermal setpoint (e.g., T_{GPU}_Setpoint_HI) and a low thermal setpoint (e.g., T_{GPU}_Setpoint_LO). The multiplexer 1902 selects the thermal setpoint based on the ambient temperature (e.g., T_{AMB}). For example, if the ambient temperature (e.g., T_{AMB}) is above a threshold ambient temperature value, the ambient temperature is deemed to be high, and the high setpoint (e.g., T_{SOC}_Setpoint_HI (e.g., 90° C.)), is selected. However, if T_{AMB} is beneath the threshold value, the ambient temperature is deemed to be low and the lower reference value, T_{GPU}_Setpoint_LO (e.g., 70° C.), is selected.

Based on the ambient temperature, a desired thermal setpoint (e.g., operating temperature) is established for the GPU (e.g., T_{GPU}_Setpoint) and used as a reference for the control loop. Next, the difference unit 1411 generates a series of error terms by taking the difference between the actual GPU temperature (e.g., as measured by the GPU (T_{GPU})) and the desired GPU temperature (e.g., T_{GPU}_Setpoint). Here, the difference unit 1904 acts as a comparator that compares T_{GPU} and T_{GPU}_Setpoint and provides a magnitude of the difference between T_{GPU} and T_{GPU}_Setpoint and/or a polarity that reflects which of T_{GPU} and T_{GPU}_Setpoint is greater than the other.

The error terms are then added (e.g., accumulated, integrated) by a summation unit 1906. The summed error terms generate the fan RPM control setting that is sent to the fans 1708. Air blown by the fans 1403 cools the GPU which affects a next T_{GPU} reading. Over time the control loop drives the error term towards zero to reach a stable steady state. As such, the steady state corresponds to an RPM fan setting that causes T_{GPU} to be equal to the T_{GPU}_SETPOINT reference temperature.

FIG. 20 is an illustration of example operations of the control circuitry of FIG. 18 for fan control using ambient temperature. The illustration of FIG. 20 includes the temperature sensor circuitry 1802, the fan control circuitry 1808, and the graphical processing unit 1702. The example graphical processing unit 1702 includes the heatsink 1706, the fan 1708, a thermal interface material 2006, a system on a chip (SoC) 2004, and the electronic host 1700. The second sensor 1713 is positioned at the interface between the heatsink 1706 and the fan 1708 (e.g., on a chassis of the GPU 1702). Thus, the GPU 1702 includes an integrated circuit (e.g., the SoC 2004), a heatsink (e.g., the heatsink 1706) thermally coupled (e.g., by the thermal interface material 2006) to the integrated circuit, and a fan (e.g., the fan 1708). The GPU 1702 further includes a first temperature sensor (e.g., integrated into the SoC 2004) to output a first signal indicative of a temperature of the integrated circuit, and a second temperature sensor (e.g., the second temperature sensor 1713) to output a second signal indicative of a temperature ambient to the integrated circuit.

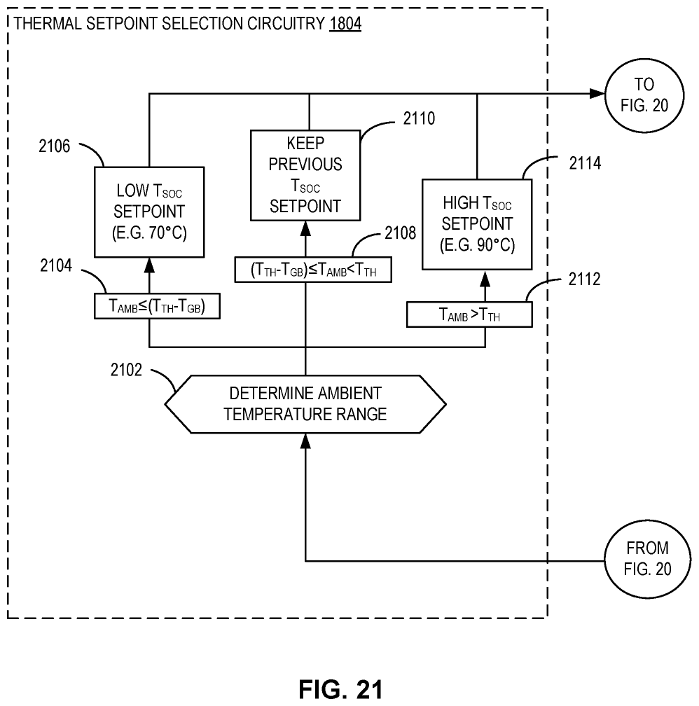

At block 2012, the temperature sensor circuitry 1802 retrieves a GPU SoC temperature (T_{SOC}) generated by the SoC 2004. The temperature sensor circuitry 1802 then provides the T_{SOC} to the fan control circuitry 1808. The temperature sensor circuitry 1802 also, at block 2008, reads an ambient temperature captured by the second ambient temperature sensor 1713. The ambient temperature is transmitted to the thermal setpoint selection circuitry 1804, to undergo operations that are illustrated in FIG. 21.

At block 2015, the fan control circuitry 1808 determines an RPM target. At block 2016, the fan control circuitry 1808 receives a T_{SOC} thermal setpoint from the thermal setpoint selection circuitry 1804 (e.g., block 2014) and a current RPM read (e.g., block 2018) from the fan 1708. Using this information and the RPM target, the fan control circuitry compares an RPM change (e.g., ΔRPM) to any applicable RPM change limits. The instructions of block 2016 continues at one of blocks 2026, 2019, or 2022.

If, at block 2016, the RPM change (e.g., ΔRPM) is within the ΔRPM limit (e.g., Block 2026), the fan control circuitry 1808 sets the RPM limit to the RPM target and control continues to block 2027.

If, at block 2016, the RPM change (e.g., ΔRPM) is greater than max ΔRPM increase (e.g., Block 2019), the fan control circuitry 1808 sets the current RPM equal to the sum of a current RPM and a max ΔRPM increase before control continues at block 2020.

If, at block 2016, the RPM change (e.g., ΔRPM) is less than a maximum ΔRPM decrease (e.g., Block 2022), the fan control circuitry 1808 sets the current RPM equal to the sum of a current RPM and a max ΔRPM decrease before control continues at block 2024.

At block 2028, the fan control circuitry 1808 checks if the current RPM is less than or equal to a maximum RPM (e.g., based on acoustic limits). If so, at block 2030, the fan control circuitry 1808 provides a signal to the fan 1708 to set the RPM equal to the maximum RPM. Otherwise, at block 2029, the fan control circuitry 1808 sets the RPM to the set RPM.

Therefore, an example apparatus designed in accordance with FIG. 10 may include: means for removing heat from an integrated circuit (e.g., the heatsink 1706); means for generating airflow (e.g., the fan 1708); first means for sensing a temperature of the integrated circuit (e.g., the first temperature sensor of the SOC 2004); second means for sensing a temperature ambient to the integrated circuit (e.g., the second temperature sensor 1713); and means for selecting a thermal setpoint (e.g., the thermal setpoint selection circuitry 1804) to: set a first thermal setpoint in response to the ambient temperature exceeding a threshold value plus a gap band temperature value; and set a second thermal setpoint in response to the ambient temperature being less than the threshold value minus the gap band temperature value.

The first selection occurs if, at block 2102, the thermal setpoint selection circuitry 1804 determines that the ambient temperature is less than or equal to the thermal threshold minus a gap band temperature (e.g., Block 2104). In such a case, the low thermal setpoint is set (e.g., Block 2106).

The second option occurs if, at block 2102, thermal setpoint selection circuitry 1804 determines that the ambient temperature is less than the thermal threshold but greater than or equal to the thermal threshold minus a gap band temperature value (e.g., Block 2108). In such a case, the previous thermal setpoint is maintained (e.g., Block 2110).

The third option occurs if, at block 2102, thermal setpoint selection circuitry 1804 determines that the ambient temperature is greater than the thermal threshold. In such a case, the high thermal threshold is selected (e.g., Block 2114). Control continues at FIG. 20.

A flowchart representative of example machine readable instructions,

which may be executed to configure processor circuitry to implement the control circuitry 1704 of FIG. 17, is shown in FIG. 22. The machine readable instructions may be one or more executable programs or portion(s) of an executable program for execution by processor circuitry, such as the processor circuitry 2512 shown in the example processor platform 2500 discussed below in connection with FIG. 25 and/or the example processor circuitry discussed below in connection with FIGS. 26 and/or 27. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowchart illustrated in FIGS. 22-23, many other methods of implementing the example control circuitry 1704 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 20-23 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 22 is a flowchart representative of machine readable instructions that may be executed by processor circuitry to implement the control circuitry 1704 of FIG. 17. At block 2202, the example temperature sensor circuitry 1802 determines a first temperature of a semiconductor at a first location. For example, the temperature sensor circuitry 1802 may determine a first temperature (e.g., a GPU die temperature, an infrastructure processing unit temperature, a neural network accelerator temperature, etc.,) at a first location (e.g., the GPU die, the IPU die, the neural network accelerator die) that is associated with second programmable circuitry (e.g., the GPU, the IPU, the neural network accelerator).

At block 2204, the example temperature sensor circuitry 1802 determines an ambient temperature at a second location. For example, the temperature sensor circuitry 1802 may determine a second temperature (e.g., an ambient temperature, a room temperature, etc.) at a second location (e.g., ambient to the GPU, ambient to the IPU) that is different than the first location. In some examples, the temperature sensor circuitry 1802 may determine one or more additional temperatures at various locations that are associated with a processing unit (e.g., a GPU, a processor, etc.).

At block 2206, the thermal setpoint selection circuitry 1804 compares the ambient temperature to threshold value. The thermal setpoint selection circuitry 1804 may also determine a threshold value (e.g., a threshold ambient temperature value) for use in determining which thermal setpoint to assign to the processor unit (e.g., based on the ambient temperature). For example, the threshold ambient temperature value (e.g., 27 degrees Celsius) may be associated with a temperature at which a user is more accepting of increased fan noise, as the environment feels warm to the user. When the user is in a relatively cold environment (e.g., 11 degrees Celsius), the user may find such fan noise unacceptable.

At block 2208, the thermal setpoint selection circuitry 1804 selects a thermal setpoint. The operations of block 2208 are described in further detail in association with FIG. 23. Finally, at block 2210 the fan control circuitry 1808 modulates (e.g., change an RPM of a fan) to satisfy the thermal setpoint. For example, to change the fan speed of a fan associated with programmable circuitry (e.g., the GPU 1702 of FIG. 7) the fan control circuitry 1808 may determine a current rotational speed of the fan. Then, the fan control circuitry 1808 may determine a target rotational speed for the fan. The fan control circuitry 1808 may then set the fan to a speed that is approximately the current rotational speed plus a threshold rotational change maximum. The instructions end.

FIG. 23 is a flowchart representative of machine readable instructions that may be executed by processor circuitry to implement the thermal setpoint selection circuitry 1804 of FIG. 18.

The instructions of FIG. 23 start at block 2302, at which the thermal setpoint selection circuitry 1804 determines if an ambient temperature less than or equal to a thermal threshold minus a gap band temperature. If so (Block 2302: YES), then the thermal setpoint selection circuitry 1804 selects the low setpoint at block 2304.

Otherwise (Block 2302: NO), control continues to block 2306. At block 2306, the thermal setpoint selection circuitry 1804 determines if the ambient temperature is greater than the thermal threshold plus the gap band. If so (Block 2306: YES), thermal setpoint selection circuitry 1804 selects the high setpoint at block 2308. Otherwise (Block 2306: NO), the thermal setpoint selection circuitry 1804 maintains the existing thermal setpoint at block 2312. The instructions return to block 2210.

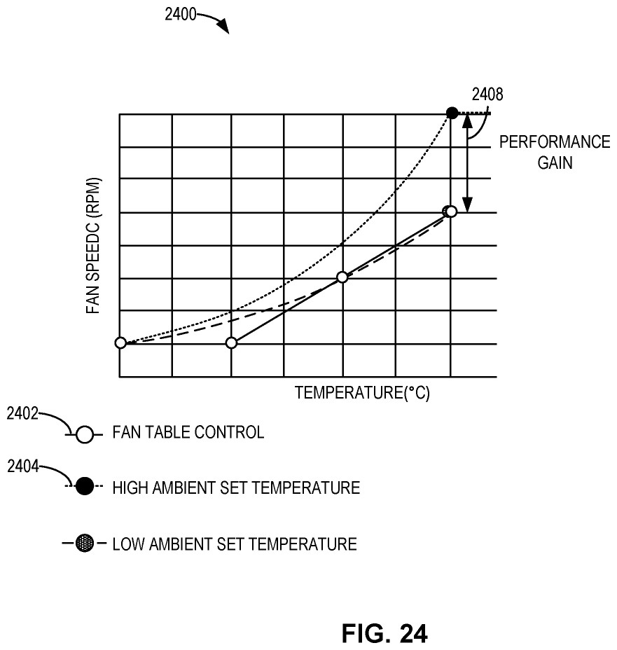

FIG. 24 is a graph of performance gains that may be achieved using techniques described herein. In the graph 2400, the fan table control data 2402 is representative of prior solutions that do not include the performance improvements through use of ambient temperature for set target temperature fan control. As shown by the performance gain 2408, examples disclosed herein that utilize the high ambient set temperature 2404 can achieve improved performance at a given temperature.

FIG. 25 is a block diagram of an example processor platform 2500 structured to execute and/or instantiate the machine readable instructions and/or the operations of FIGS. 20-23 to implement the control circuitry 1704 of FIG. 18. The processor platform 2500 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 2500 of the illustrated example includes processor circuitry 2512. The processor circuitry 2512 of the illustrated example is hardware. For example, the processor circuitry 2512 can be implemented by one or more integrated circuits, logic circuits, FPGAs, microprocessors, CPUs, GPUs, DSPs, and/or microcontrollers from any desired family or manufacturer. The processor circuitry 2512 may be implemented by one or more semiconductor based (e.g., silicon based) devices. In this example, the processor circuitry 2512 implements the temperature sensor circuitry 1802, the thermal setpoint selection circuitry 1804, the condition determination circuitry 1806, the fan control circuitry 1808, the communication circuitry 1810, and the data storage circuitry 1812.

The processor circuitry 2512 of the illustrated example includes a local memory 2513 (e.g., a cache, registers, etc.). The processor circuitry 2512 of the illustrated example is in communication with a main memory including a volatile memory 2514 and a non-volatile memory 2516 by a bus 2518. The volatile memory 2514 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 2516 may be implemented by flash memory and/or any other desired type of memory device. Access to the main memory 2514, 2516 of the illustrated example is controlled by a memory controller 2517.

The processor platform 2500 of the illustrated example also includes interface circuitry 2520. The interface circuitry 2520 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 2522 are connected to the interface circuitry 2520. The input device(s) 2522 permit(s) a user to enter data and/or commands into the processor circuitry 2512. The input device(s) 2522 can be implemented by, for example, an audio sensor, a microphone, a camera (still or video), a keyboard, a button, a mouse, a touchscreen, a track-pad, a trackball, an isopoint device, and/or a voice recognition system.

One or more output devices 2524 are also connected to the interface circuitry 2520 of the illustrated example. The output device(s) 2524 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 2520 of the illustrated example, thus, typically includes a graphics driver card, a graphics driver chip, and/or graphics processor circuitry such as a GPU.

The interface circuitry 2520 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 2526. The communication can be by, for example, an Ethernet connection, a digital subscriber line (DSL) connection, a telephone line connection, a coaxial cable system, a satellite system, a line-of-site wireless system, a cellular telephone system, an optical connection, etc.

The processor platform 2500 of the illustrated example also includes one or more mass storage devices 2528 to store software and/or data. Examples of such mass storage devices 2528 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives.

The machine readable instructions 2532, which may be implemented by the machine readable instructions of FIGS. 20-23, may be stored in the mass storage device 2528, in the volatile memory 2514, in the non-volatile memory 2516, and/or on a removable non-transitory computer readable storage medium such as a CD or DVD.

FIG. 26 is a block diagram of an example implementation of the processor circuitry 2512 of FIG. 25. In this example, the processor circuitry 2512 of FIG. 25 is implemented by a microprocessor 2600. For example, the microprocessor 2600 may be a general purpose microprocessor (e.g., general purpose microprocessor circuitry). The microprocessor 2600 executes some or all of the machine readable instructions of the flowchart of FIGS. 20-23 to effectively instantiate the control circuitry 1704 of FIG. 18 as logic circuits to perform the operations corresponding to those machine readable instructions. In some such examples, the control circuitry 1704 of FIG. 18 is instantiated by the hardware circuits of the microprocessor 2600 in combination with the instructions. For example, the microprocessor 2600 may be implemented by multi-core hardware circuitry such as a CPU, a DSP, a GPU, an XPU, etc. Although it may include any number of example cores 2602 (e.g., 1 core), the microprocessor 2600 of this example is a multi-core semiconductor device including N cores. The cores 2602 of the microprocessor 2600 may operate independently or may cooperate to execute machine readable instructions. For example, machine code corresponding to a firmware program, an embedded software program, or a software program may be executed by one of the cores 2602 or may be executed by multiple ones of the cores 2602 at the same or different times. In some examples, the machine code corresponding to the firmware program, the embedded software program, or the software program is split into threads and executed in parallel by two or more of the cores 2602. The software program may correspond to a portion or all of the machine readable instructions and/or operations represented by the flowcharts of FIGS. 20-23.

The cores 2602 may communicate by a first example bus 2604. In some examples, the first bus 2604 may be implemented by a communication bus to effectuate communication associated with one(s) of the cores 2602. For example, the first bus 2604 may be implemented by at least one of an Inter-Integrated Circuit (I2C) bus, a Serial Peripheral Interface (SPI) bus, a PCI bus, or a PCIe bus. Additionally or alternatively, the first bus 2604 may be implemented by any other type of computing or electrical bus. The cores 2602 may obtain data, instructions, and/or signals from one or more external devices by example interface circuitry 2606. The cores 2602 may output data, instructions, and/or signals to the one or more external devices by the interface circuitry 2606. Although the cores 2602 of this example include example local memory 2620 (e.g., Level 1 (L1) cache that may be split into an L1 data cache and an L1 instruction cache), the microprocessor 2600 also includes example shared memory 2610 that may be shared by the cores (e.g., Level 2 (L2 cache)) for high-speed access to data and/or instructions. Data and/or instructions may be transferred (e.g., shared) by writing to and/or reading from the shared memory 2610. The local memory 2620 of each of the cores 2602 and the shared memory 2610 may be part of a hierarchy of storage devices including multiple levels of cache memory and the main memory (e.g., the main memory 2514, 2516 of FIG. 25). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 2602 may be referred to as a CPU, DSP, GPU, etc., or any other type of hardware circuitry. Each core 2602 includes control unit circuitry 2614, arithmetic and logic (AL) circuitry (sometimes referred to as an ALU) 2616, a plurality of registers 2618, the local memory 2620, and a second example bus 2622. Other structures may be present. For example, each core 2602 may include vector unit circuitry, single instruction multiple data (SIMD) unit circuitry, load/store unit (LSU) circuitry, branch/jump unit circuitry, floating-point unit (FPU) circuitry, etc. The control unit circuitry 2614 includes semiconductor-based circuits structured to control (e.g., coordinate) data movement within the corresponding core 2602. The AL circuitry 2616 includes semiconductor-based circuits structured to perform one or more mathematic and/or logic operations on the data within the corresponding core 2602. The AL circuitry 2616 of some examples performs integer based operations. In other examples, the AL circuitry 2616 also performs floating point operations. In yet other examples, the AL circuitry 2616 may include first AL circuitry that performs integer based operations and second AL circuitry that performs floating point operations. In some examples, the AL circuitry 2616 may be referred to as an Arithmetic Logic Unit (ALU). The registers 2618 are semiconductor-based structures to store data and/or instructions such as results of one or more of the operations performed by the AL circuitry 2616 of the corresponding core 2602. For example, the registers 2618 may include vector register(s), SIMD register(s), general purpose register(s), flag register(s), segment register(s), machine specific register(s), instruction pointer register(s), control register(s), debug register(s), memory management register(s), machine check register(s), etc. The registers 2618 may be arranged in a bank as shown in FIG. 26. Alternatively, the registers 2618 may be organized in any other arrangement, format, or structure including distributed throughout the core 2602 to shorten access time. The second bus 2622 may be implemented by at least one of an I2C bus, a SPI bus, a PCI bus, or a PCIe bus

Each core 2602 and/or, more generally, the microprocessor 2600 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 2600 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

FIG. 27 is a block diagram of another example implementation of the processor circuitry 2512 of FIG. 25. In this example, the processor circuitry 2512 is implemented by FPGA circuitry 2700. For example, the FPGA circuitry 2700 may be implemented by an FPGA. The FPGA circuitry 2700 can be used, for example, to perform operations that could otherwise be performed by the example microprocessor 2600 of FIG. 26 executing corresponding machine readable instructions. However, once configured, the FPGA circuitry 2700 instantiates the machine readable instructions in hardware and, thus, can often execute the operations faster than they could be performed by a general purpose microprocessor executing the corresponding software.

More specifically, in contrast to the microprocessor 2500 of FIG. 5 described above (which is a general purpose device that may be programmed to execute some or all of the machine readable instructions represented by the flowcharts of FIGS. 20-23 but whose interconnections and logic circuitry are fixed once fabricated), the FPGA circuitry 2700 of the example of FIG. 27 includes interconnections and logic circuitry that may be configured and/or interconnected in different ways after fabrication to instantiate, for example, some or all of the machine readable instructions represented by the flowchart of FIGS. 20-23. In particular, the FPGA circuitry 2700 may be thought of as an array of logic gates, interconnections, and switches. The switches can be programmed to change how the logic gates are interconnected by the interconnections, effectively forming one or more dedicated logic circuits (unless and until the FPGA circuitry 2700 is reprogrammed). The configured logic circuits enable the logic gates to cooperate in different ways to perform different operations on data received by input circuitry. Those operations may correspond to some or all of the software represented by the flowcharts of FIGS. 20-23. As such, the FPGA circuitry 2700 may be structured to effectively instantiate some or all of the machine readable instructions of the flowcharts of FIGS. 20-23 as dedicated logic circuits to perform the operations corresponding to those software instructions in a dedicated manner analogous to an ASIC. Therefore, the FPGA circuitry 2700 may perform the operations corresponding to the some or all of the machine readable instructions of FIGS. 20-23 faster than the general purpose microprocessor can execute the same.

In the example of FIG. 27, the FPGA circuitry 2700 is structured to be programmed (and/or reprogrammed one or more times) by an end user by a hardware description language (HDL) such as Verilog. The FPGA circuitry 2700 of FIG. 27, includes example input/output (I/O) circuitry 2702 to obtain and/or output data to/from example configuration circuitry 2704 and/or external hardware 2706. For example, the configuration circuitry 2704 may be implemented by interface circuitry that may obtain machine readable instructions to configure the FPGA circuitry 2700, or portion(s) thereof. In some such examples, the configuration circuitry 2704 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 2706 may be implemented by external hardware circuitry. For example, the external hardware 2706 may be implemented by the microprocessor 2600 of FIG. 26. The FPGA circuitry 2700 also includes an array of example logic gate circuitry 2708, a plurality of example configurable interconnections 2710, and example storage circuitry 2712. The logic gate circuitry 2708 and the configurable interconnections 2710 are configurable to instantiate one or more operations that may correspond to at least some of the machine readable instructions of FIGS. 20-23 and/or other desired operations. The logic gate circuitry 2708 shown in FIG. 27 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 2708 to enable configuration of the electrical structures and/or the logic gates to form circuits to perform desired operations. The logic gate circuitry 2708 may include other electrical structures such as look-up tables (LUTs), registers (e.g., flip-flops or latches), multiplexers, etc.

The configurable interconnections 2710 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 2708 to program desired logic circuits.

The storage circuitry 2712 of the illustrated example is structured to store result(s) of the one or more of the operations performed by corresponding logic gates. The storage circuitry 2712 may be implemented by registers or the like. In the illustrated example, the storage circuitry 2712 is distributed amongst the logic gate circuitry 2708 to facilitate access and increase execution speed.

The example FPGA circuitry 2700 of FIG. 27 also includes example Dedicated Operations Circuitry 2714. In this example, the Dedicated Operations Circuitry 2714 includes special purpose circuitry 2716 that may be invoked to implement commonly used functions to avoid the need to program those functions in the field. Examples of such special purpose circuitry 2716 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 2700 may also include example general purpose programmable circuitry 2718 such as an example CPU 2720 and/or an example DSP 2722. Other general purpose programmable circuitry 2718 may additionally or alternatively be present such as a GPU, an XPU, etc., that can be programmed to perform other operations.

Although FIGS. 26 and 27 illustrate two example implementations of the processor circuitry 2512 of FIG. 25, many other approaches are contemplated. For example, as mentioned above, modern FPGA circuitry may include an on-board CPU, such as one or more of the example CPU 2720 of FIG. 27. Therefore, the processor circuitry 2512 of FIG. 25 may additionally be implemented by combining the example microprocessor 2600 of FIG. 26 and the example FPGA circuitry 2700 of FIG. 27. In some such hybrid examples, a first portion of the machine readable instructions represented by the flowcharts of FIGS. 20-23 may be executed by one or more of the cores 2602 of FIG. 26, a second portion of the machine readable instructions represented by the flowcharts of FIGS. 20-23 may be executed by the FPGA circuitry 2700 of FIG. 27, and/or a third portion of the machine readable instructions represented by the flowcharts of FIGS. 20-23 may be executed by an ASIC. It should be understood that some or all of the control circuitry 1704 of FIG. 18 may, thus, be instantiated at the same or different times. Some or all of the circuitry may be instantiated, for example, in one or more threads executing concurrently and/or in series. Moreover, in some examples, some or all of the control circuitry 1704 of FIG. 18 may be implemented within one or more virtual machines and/or containers executing on the microprocessor.

In some examples, the processor circuitry 2512 of FIG. 25 may be in one or more packages. For example, the microprocessor 2600 of FIG. 26 and/or the FPGA circuitry 2700 of FIG. 27 may be in one or more packages. In some examples, an XPU may be implemented by the processor circuitry 2512 of FIG. 25, which may be in one or more packages. For example, the XPU may include a CPU in one package, a DSP in another package, a GPU in yet another package, and an FPGA in still yet another package.

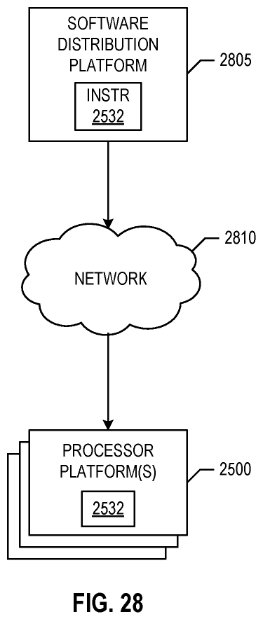

A block diagram illustrating an example software distribution platform 2805 to distribute software such as the example machine readable instructions 2532 of FIG. 25 to hardware devices owned and/or operated by third parties is illustrated in FIG. 28. The example software distribution platform 2805 may be implemented by any computer server, data facility, cloud service, etc., capable of storing and transmitting software to other computing devices. The third parties may be customers of the entity owning and/or operating the software distribution platform 2805. For example, the entity that owns and/or operates the software distribution platform 2805 may be a developer, a seller, and/or a licensor of software such as the example machine readable instructions 2532 of FIG. 25. The third parties may be consumers, users, retailers, OEMs, etc., who purchase and/or license the software for use and/or re-sale and/or sub-licensing. In the illustrated example, the software distribution platform 2805 includes one or more servers and one or more storage devices. The storage devices store the machine readable instructions 2532, which may correspond to the example machine readable instructions of FIGS. 20-23, as described above. The one or more servers of the example software distribution platform 2805 are in communication with an example network 2810, which may correspond to any one or more of the Internet and/or any of the example networks described above. In some examples, the one or more servers are responsive to requests to transmit the software to a requesting party as part of a commercial transaction. Payment for the delivery, sale, and/or license of the software may be handled by the one or more servers of the software distribution platform and/or by a third party payment entity. The servers enable purchasers and/or licensors to download the machine readable instructions 2532 from the software distribution platform 2805. For example, the software, which may correspond to the example machine readable instructions of FIGS. 20-23, may be downloaded to the example processor platform 2500, which is to execute the machine readable instructions 2532 to implement the control circuitry 1704. In some examples, one or more servers of the software distribution platform 2805 periodically offer, transmit, and/or force updates to the software (e.g., the example machine readable instructions 2532 of FIG. 25) to ensure improvements, patches, updates, etc., are distributed and applied to the software at the end user devices.

From the foregoing, it will be appreciated that example systems, methods, apparatus, and articles of manufacture have been disclosed that improve set target temperature fan control using ambient temperature. Disclosed systems, methods, apparatus, and articles of manufacture improve the efficiency of using a computing device by allowing for greater performance when ambient temperature is high and less power leakage when ambient temperature is low. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture for fan control based on ambient temperature are disclosed herein. Further examples and combinations thereof include the following:

Example 1 includes a system comprising interface circuitry, first programmable circuitry, and instructions to cause the first programmable circuitry to determine, based on a first signal output by a first sensor, a first temperature at a first location that is associated with second programmable circuitry, determine, based on a second signal output by a second sensor, a second temperature at a second location that is different than the first location, set a first thermal setpoint for the second programmable circuitry in response to the second temperature failing to satisfy a threshold value, and set a second thermal setpoint for the second programmable circuitry in response to the second temperature satisfying the threshold value, wherein the second thermal setpoint is higher than the first thermal setpoint.

Example 2 includes the system of example 1, wherein the first programmable circuitry is to, based on control of a rotational speed of a fan, cause the second programmable circuitry to satisfy (1) the first thermal setpoint, or (2) the second thermal setpoint.

Example 3 includes the system of example 2, wherein the threshold value is a first threshold value, and to control the rotational speed of the fan, the first programmable circuitry is to determine a current rotational speed of the fan, determine a target rotational speed for the fan, determine that a difference between the current rotational speed and the target rotational speed satisfies a second threshold value, and set the fan to a speed that is approximately the current rotational speed plus the second threshold value.

Example 4 includes the system of example 3, wherein the first programmable circuitry causes the fan to accelerate more rapidly than the first programmable circuitry causes the fan to decelerate.

Example 5 includes the system of example 3, wherein the first programmable circuitry is to control the fan based on one or more of ambient sound at the second location or a workload associated with the second programmable circuitry.

Example 6 includes the system of example 2, wherein the first programmable circuitry is to maintain a thermal setpoint when the second temperature does not satisfy a guard-band temperature threshold.

Example 7 includes the system of example 1, wherein the second programmable circuitry is at least one of a graphics processor, an artificial intelligence accelerator, an infrastructure processing unit, or a network processor.

Example 8 includes an apparatus comprising an integrated circuit, a heatsink thermally coupled to the integrated circuit, a fan, a first temperature sensor to output a first signal indicative of a temperature of the integrated circuit, a second temperature sensor to output a second signal indicative of a temperature ambient to the integrated circuit, and processor circuitry to set a first thermal setpoint in response to the ambient temperature exceeding a threshold value plus a gap band temperature value, and set a second thermal setpoint in response to the ambient temperature being less than the threshold value minus the gap band temperature value.

Example 9 includes the apparatus of example 8, wherein the second temperature sensor is located at a fan intake of a chassis that at least partially encloses the integrated circuit.

Example 10 includes the apparatus of example 8, wherein the second temperature sensor is located outside a chassis that at least partially encloses the integrated circuit.

Example 11 includes the apparatus of example 8, wherein the first temperature sensor is part of the processor circuitry.

Example 12 includes the apparatus of example 8, wherein the processor circuitry is to control a speed of the fan to maintain the first thermal setpoint or the second thermal setpoint.

Example 13 includes the apparatus of example 8, wherein the first signal is carried by the integrated circuit to the processor circuitry.

Example 14 includes the apparatus of example 8, wherein the processor circuitry is at least one of a graphics processor, an artificial intelligence accelerator, an infrastructure processing unit, or a network processor.

Example 15 includes a non-transitory computer readable storage medium comprising instructions which, when executed by first programmable circuitry, cause the first programmable circuitry to determine, based on a first signal output by a first sensor, a first temperature at a first location that is associated with second programmable circuitry, determine, based on a second signal output by a second sensor, a second temperature at a second location that is different than the first location, set a first thermal setpoint for the second programmable circuitry in response to the second temperature failing to satisfy a threshold value, and set a second thermal setpoint for the second programmable circuitry in response to the second temperature satisfying the threshold value, wherein the second thermal setpoint is higher than the first thermal setpoint.

Example 16 includes the non-transitory computer readable storage medium of example 15, wherein the instructions, when executed, cause the first programmable circuitry to, based on control of a rotational speed of a fan, cause the second programmable circuitry to satisfy (1) the first thermal setpoint, or (2) the second thermal setpoint.

Example 17 includes the non-transitory computer readable storage medium of example 16, wherein the threshold value is a first threshold value, and to control the rotational speed of the fan, the instructions are to cause the first programmable circuitry is to determine a current rotational speed of the fan, determine a target rotational speed for the fan, determine that a difference between the current rotational speed and the target rotational speed satisfies a second threshold value, and set the fan to a speed that is approximately the current rotational speed plus the second threshold value.

Example 18 includes the non-transitory computer readable storage medium of example 17, wherein the instructions, when executed, cause the first programmable circuitry to causes the fan to accelerate more rapidly than the first programmable circuitry causes the fan to decelerate.

Example 19 includes the non-transitory computer readable storage medium of example 17, wherein the instructions, when executed, cause the first programmable circuitry to control the fan based on one or more of ambient sound at the second location or a workload associated with the second programmable circuitry.

Example 20 includes the non-transitory computer readable storage medium of example 16, wherein the first programmable circuitry is to maintain a thermal setpoint when the second temperature does not satisfy a guard-band temperature threshold.

Example 21 includes an apparatus comprising means for determining a condition based on a first signal output by a first sensor at a first location and a second signal output by a second sensor at a second location that is different than the first location, and means for selecting one of first or second thermal setpoints based on the condition.

Example 22 includes the apparatus of example 21, further including means for controlling a fan.

Example 23 includes the apparatus of example 22, wherein the means for controlling the fan causes the fan to accelerate more rapidly in a first direction than a second direction opposite the first direction.

Example 24 includes the apparatus of example 22, wherein the means for controlling the fan is to control the fan based on one or more of ambient sound at the second location or a workload associated with the second programmable circuitry.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

1. A system comprising:
interface circuitry;
first programmable circuitry; and
instructions to cause the first programmable circuitry to:
determine, based on a first signal output by a first sensor, a first temperature at a first location that is associated with second programmable circuitry;
determine, based on a second signal output by a second sensor, a second temperature at a second location that is different than the first location;
set a first thermal setpoint for the second programmable circuitry in response to the second temperature failing to satisfy a threshold value; and
set a second thermal setpoint for the second programmable circuitry in response to the second temperature satisfying the threshold value, wherein the second thermal setpoint is higher than the first thermal setpoint.

2. The system of claim 1, wherein the first programmable circuitry is to, based on control of a rotational speed of a fan, cause the second programmable circuitry to satisfy: (1) the first thermal setpoint; or (2) the second thermal setpoint.

3. The system of claim 2, wherein the threshold value is a first threshold value, and to control the rotational speed of the fan, the first programmable circuitry is to:
determine a current rotational speed of the fan;
determine a target rotational speed for the fan;
determine that a difference between the current rotational speed and the target rotational speed satisfies a second threshold value; and
set the fan to a speed that is approximately the current rotational speed plus the second threshold value.

4. The system of claim 3, wherein the first programmable circuitry causes the fan to accelerate more rapidly than the first programmable circuitry causes the fan to decelerate.

5. The system of claim 3, wherein the first programmable circuitry is to control the fan based on one or more of ambient sound at the second location or a workload associated with the second programmable circuitry.

6. The system of claim 2, wherein the first programmable circuitry is to maintain a thermal setpoint when the second temperature does not satisfy a guard-band temperature threshold.

7. The system of claim 1, wherein the second programmable circuitry is at least one of:
a graphics processor;
an artificial intelligence accelerator;
an infrastructure processing unit; or
a network processor.

8. An apparatus comprising:
an integrated circuit;
a heatsink thermally coupled to the integrated circuit;
a fan;
a first temperature sensor to output a first signal indicative of a temperature of the integrated circuit;
a second temperature sensor to output a second signal indicative of a temperature ambient to the integrated circuit; and
processor circuitry to:
set a first thermal setpoint in response to the ambient temperature exceeding a threshold value plus a gap band temperature value; and
set a second thermal setpoint in response to the ambient temperature being less than the threshold value minus the gap band temperature value.

9. The apparatus of claim 8, wherein the second temperature sensor is located at a fan intake of a chassis that at least partially encloses the integrated circuit.

10. The apparatus of claim 8, wherein the second temperature sensor is located outside a chassis that at least partially encloses the integrated circuit.

11. The apparatus of claim 8, wherein the first temperature sensor is part of the processor circuitry.

12. The apparatus of claim 8, wherein the processor circuitry is to control a speed of the fan to maintain the first thermal setpoint or the second thermal setpoint.

13. The apparatus of claim 8, wherein the first signal is carried by the integrated circuit to the processor circuitry.

14. The apparatus of claim 8, wherein the processor circuitry is at least one of:
a graphics processor;
an artificial intelligence accelerator;
an infrastructure processing unit; or
a network processor.

15. A non-transitory computer readable storage medium comprising instructions which, when executed by first programmable circuitry, cause the first programmable circuitry to:
determine, based on a first signal output by a first sensor, a first temperature at a first location that is associated with second programmable circuitry;
determine, based on a second signal output by a second sensor, a second temperature at a second location that is different than the first location;
set a first thermal setpoint for the second programmable circuitry in response to the second temperature failing to satisfy a threshold value; and
set a second thermal setpoint for the second programmable circuitry in response to the second temperature satisfying the threshold value, wherein the second thermal setpoint is higher than the first thermal setpoint.

16. The non-transitory computer readable storage medium of claim 15, wherein the instructions, when executed, cause the first programmable circuitry to, based on control of a rotational speed of a fan, cause the second programmable circuitry to satisfy: (1) the first thermal setpoint; or (2) the second thermal setpoint.

17. The non-transitory computer readable storage medium of claim 16, wherein the threshold value is a first threshold value, and to control the rotational speed of the fan, the instructions are to cause the first programmable circuitry is to:
determine a current rotational speed of the fan;
determine a target rotational speed for the fan;
determine that a difference between the current rotational speed and the target rotational speed satisfies a second threshold value; and
set the fan to a speed that is approximately the current rotational speed plus the second threshold value.

18. The non-transitory computer readable storage medium of claim 17, wherein the instructions, when executed, cause the first programmable circuitry to causes the fan to accelerate more rapidly than the first programmable circuitry causes the fan to decelerate.

19. The non-transitory computer readable storage medium of claim 17, wherein the instructions, when executed, cause the first programmable circuitry to control the fan based on one or more of ambient sound at the second location or a workload associated with the second programmable circuitry.

20. The non-transitory computer readable storage medium of claim 16, wherein the first programmable circuitry is to maintain a thermal setpoint when the second temperature does not satisfy a guard-band temperature threshold.

21.-24. (canceled)
